(19) United States
(12) Patent Application Publication
(10) Pub. No.: US 2025/0107179 A1
(43) Pub. Date: Mar. 27, 2025

(54) INTEGRATED CIRCUIT DEVICE

(71) Applicant: SAMSUNG ELECTRONICS CO., LTD., Suwon-si (KR)

(72) Inventors: Wonkeun CHUNG, Suwon-si (KR); Geunwoo KIM, Suwon-si (KR); Wandon KIM, Suwon-si (KR); Hyoseok CHOI, Suwon-si (KR)

(73) Assignee: SAMSUNG ELECTRONICS CO., LTD., Suwon-si (KR)

(21) Appl. No.: 18/663,867

(22) Filed: May 14, 2024

(30) Foreign Application Priority Data
Sep. 26, 2023 (KR) 10-2023-0129575

(51) Int. Cl. H01L 29/06; H01L 23/522; H01L 23/528; H01L 27/092; H01L 29/417; H01L 29/423; H01L 29/49; H01L 29/66; H01L 29/775; H01L 29/786

(52) U.S. Cl. CPC H10D 62/121; H01L 23/5226; H01L 23/5283; H10D 30/43; H10D 30/6729; H10D 30/6735; H10D 30/6757; H10D 64/021; H10D 64/665; H10D 84/85

(57) ABSTRACT

Provided is an integrated circuit device and a method of manufacturing same, the integrated circuit device including: a fin-type active region on a substrate, a pair of insulating spacers on the fin-type active region and the substrate and defining a first space, a gate dielectric film contacting the gate line in the first space, a gate contact plug having a conductive bottom surface contacting a top contact portion of the gate line in the first space, and a capping insulating pattern including an insulating bottom surface, a pair of first insulating sidewalls, and a second insulating sidewall, the insulating bottom surface contacting a local top surface of the gate line in the first space, the pair of first insulating sidewalls contacting the pair of insulating spacers, and the second insulating sidewall contacting the gate contact plug, wherein an insulating top surface of the capping insulating pattern and a conductive top surface of the gate contact plug extend along one plane.

### CROSS-REFERENCE TO RELATED APPLICATION

This application is based on and claims priority under 35 U.S.C. § 119 to Korean Patent Application No. 10-2023-0129575, filed on Sep. 26, 2023, in the Korean Intellectual Property Office, the disclosure of which is incorporated by reference herein in its entirety.

### BACKGROUND

### 1. Field

The disclosure relates to an integrated circuit (IC) device, and more particularly, to an IC device including a gate line.

### 2. Description of Related Art

The downscaling of IC devices has rapidly progressed due to the development of electronics technology. Thus, gate lines included in the IC devices and contact structures connected to the gate lines are being reduced in terms of linewidth and pitch. Accordingly, it is necessary to develop an IC device capable of inhibiting an increase in the resistance of the contact structure and improving electrical properties and reliability.

### SUMMARY

Provided is an integrated circuit (IC) device, which may inhibit a resistance of a contact structure connected to a gate line from increasing and improve electrical properties and reliability.

According to an aspect of the disclosure, an integrated circuit device includes: a fin-type active region extending in a first lateral direction on a substrate; a pair of insulating spacers extending in a second lateral direction on the fin-type active region and the substrate, wherein the pair of insulating spacers defining a first space, and the second lateral direction intersects with the first lateral direction; a gate line covering the fin-type active region in the first space and extending in the second lateral direction; a gate dielectric film in contact with a bottom surface of the gate line and sidewalls of the gate line in the first space, the gate dielectric film extending in the second lateral direction; a gate contact plug having a conductive bottom surface in contact with a top contact portion of a top surface of the gate line in the first space; and a capping insulating pattern including an insulating bottom surface, a pair of first insulating sidewalls, and a second insulating sidewall, wherein the insulating bottom surface is in contact with a local top surface adjacent to the top contact portion of the top surface of the gate line in the first space, the pair of first insulating sidewalls are in contact with the pair of insulating spacers, and the second insulating sidewall is in contact with the gate contact plug, and wherein an insulating top surface of the capping insulating pattern and a conductive top surface of the gate contact plug extend along one plane.

According to an aspect of the disclosure, an integrated circuit device includes: a substrate including a first device region and a second device region; a fin-type active region on the substrate in the first device region, the fin-type active region extending in a first lateral direction; a first gate line extending in a second lateral direction on the fin-type active region and the substrate, the first gate line including a first width in the first lateral direction, wherein the first gate line is in the first device region, and the second lateral direction intersects with the first lateral direction; a first gate dielectric film covering a bottom surface of the first gate line and sidewalls of the first gate line, the first gate dielectric film extending in the second lateral direction; a gate contact plug including a conductive bottom surface in contact with a top contact portion of a top surface of the first gate line; a capping insulating pattern including an insulating bottom surface and an insulating sidewall, wherein the insulating bottom surface is in contact with a local top surface adjacent to the top contact portion of the top surface of the first gate line, and the insulating sidewall is in contact with the gate contact plug; a second gate line on an active region in the second device region, the second gate line including a second width in the first lateral direction, wherein the second gate line is in the second device region, and the second width is greater than the first width; and a second gate dielectric film between the second gate line and the active region, wherein, in the first device region, an insulating top surface of the capping insulating pattern and a conductive top surface of the gate contact plug extend along one plane, and wherein the conductive top surface of the gate contact plug in the first device region includes a same material as a top surface of the second gate line in the second device region.

According to an aspect of the disclosure, an integrated circuit device includes: a substrate including an N-type metal-oxide-semiconductor (NMOS) transistor region and a P-type metal-oxide-semiconductor (PMOS) transistor region; a fin-type active region extending in a first lateral direction in the NMOS transistor region or the PMOS transistor region; a nanosheet stack separate from a fin top surface of the fin-type active region in a vertical direction, wherein the nanosheet stack faces the fin top surface of the fin-type active region, and the nanosheet stack includes at least one nanosheet; a pair of insulating spacers extending in a second lateral direction in a selected one of the NMOS transistor region and the PMOS transistor region corresponding to a location of the fin-type active region, the pair of insulating spacers defining a first space, wherein the second lateral direction intersects with the first lateral direction; a gate line surrounding the at least one nanosheet and extending in the second lateral direction in the first space; a gate dielectric film extending in the second lateral direction in the first space, the gate dielectric film including a portion in contact with a bottom surface and side surfaces of the gate line and each of the at least one nanosheet; a gate contact plug including a conductive bottom surface in contact with a top contact portion of the gate line in the first space; a capping insulating pattern including an insulating bottom surface, a pair of first insulating sidewalls, and a second insulating sidewall, wherein the insulating bottom surface is in contact with a local top surface adjacent to the top contact portion of the gate line in the first space, the pair of first insulating sidewalls are in contact with the pair of insulating spacers, and the second insulating sidewall is in contact with the gate contact plug, and wherein an insulating top surface of the capping insulating pattern and a conductive top surface of the gate contact plug extend along one plane.

### BRIEF DESCRIPTION OF DRAWINGS

Embodiments of the disclosure will be more clearly understood from the following detailed description taken in conjunction with the accompanying drawings, in which:

FIG. 1 is a plan layout diagram of an integrated circuit (IC) device according to one or more embodiments;

FIG. 2A is a cross-sectional view taken along line X1-X1′ of FIG. 1;

FIG. 2B is a cross-sectional view taken along line Y1-Y1′ of FIG. 1;

FIGS. 2C and 2D are each an enlarged perspective view of a partial region of the IC device shown in FIGS. 1, 2A, and 2B;

FIG. 2E is an enlarged cross-sectional view of portions “EX1” and “EX2” of FIG. 2A;

FIGS. 3, 4, 5, 6A, 6B, 6C, 6D, 6E, 6F, 6G and 6H, 7A, and 7B are cross-sectional views of IC devices according to one or more embodiments;

FIG. 8 is a plan layout diagram of some components of an IC device according to one or more embodiments;

FIG. 9A is a cross-sectional view of some components corresponding to each of a cross-section taken along line X1A-X1A′ and a cross-section taken along line X1B-X1B′ of FIG. 8;

FIG. 9B is a cross-sectional view of some components corresponding to each of a cross-section taken along line X2A-X2A′ and a cross-section taken along line X2B-X2B′ of FIG. 8;

FIG. 10A is an enlarged cross-sectional view of portions “EX51” and “EX52” of FIG. 9A;

FIG. 10B is an enlarged cross-sectional view of portions “EX52” and “EX54” of FIG. 9B;

FIGS. 11A and 11B are cross-sectional views of an IC device according to one or more embodiments;

FIGS. 12A and 12B are cross-sectional views of an IC device according to one or more embodiments;

FIGS. 13A and 13B are cross-sectional views of an IC device according to one or more embodiments;

FIGS. 14A, 14B, 15A, 15B, 16, 17, 18, 19 and 20 are cross-sectional views of a process sequence of a method of manufacturing an IC device, according to one or more embodiments, wherein FIGS. 14A, 15A, and 16 to 20 are cross-sectional views of example cross-sectional structures of a portion corresponding to a cross-section taken along line X1-X1′ of FIG. 1, according to a process sequence, and FIGS. 14B and 15B are cross-sectional views of example cross-sectional structures of a portion corresponding to a cross-section taken along line Y1-Y1′ of FIG. 1, according to a process sequence;

FIGS. 21A, 21B, 21C, and 21D are cross-sectional views of a process sequence of a method of manufacturing an IC device, according to one or more embodiments; and

FIGS. 22A, 22B, 22C, and 22D are cross-sectional views of a process sequence of a method of manufacturing an IC device, according to one or more embodiments.

### DETAILED DESCRIPTION

Hereinafter, embodiments will be described in detail with reference to the accompanying drawings. The same reference numerals are used to denote the same elements in the drawings, and repeated descriptions thereof are omitted.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms first, second, third, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any methods described herein, each step may be implemented in an order different from the illustrated order unless the context clearly indicates otherwise.

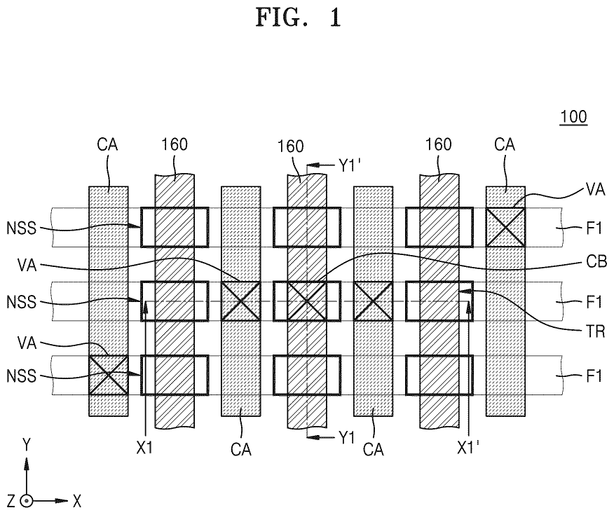

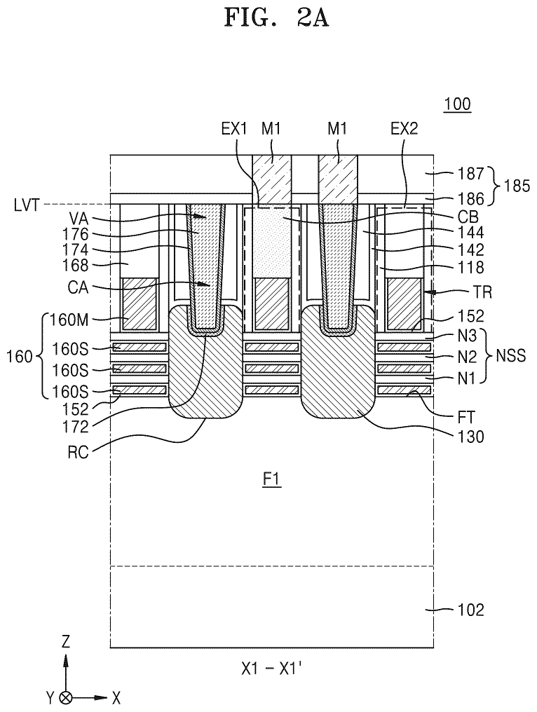

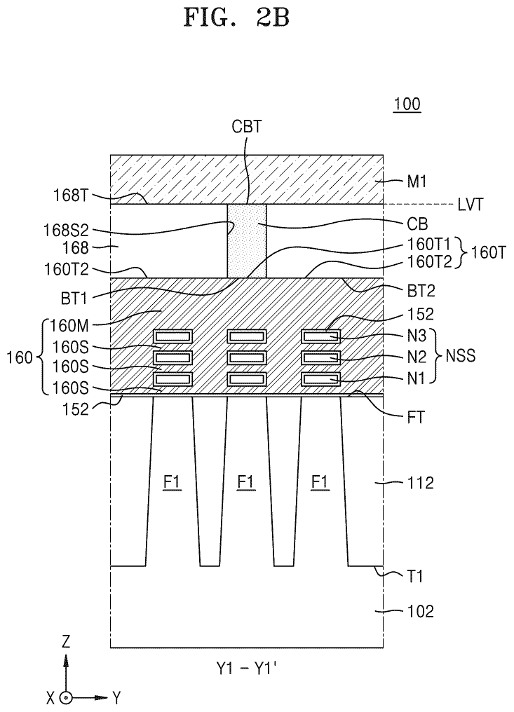

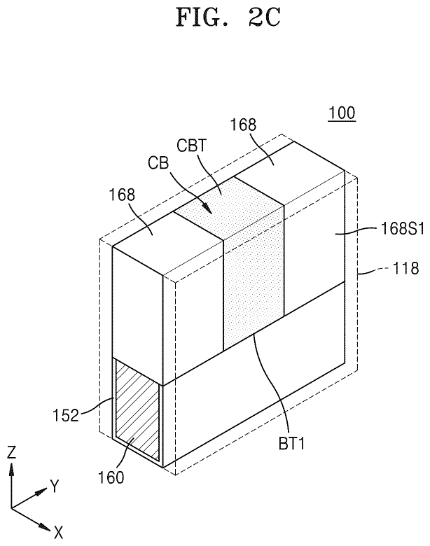

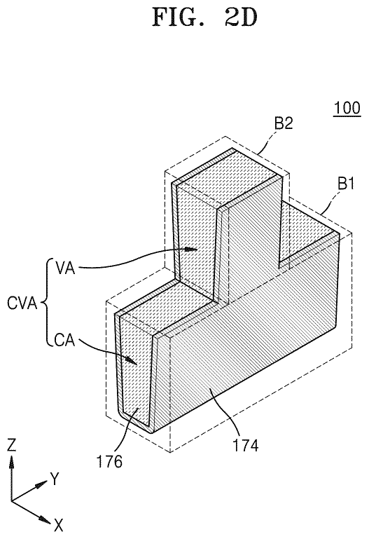

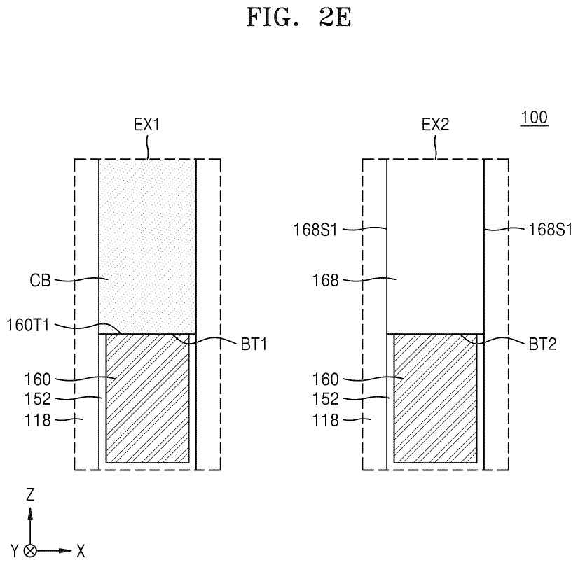

FIG. 1 is a plan layout diagram of an integrated circuit (IC) device 100 according to one or more embodiments. FIG. 2A is a cross-sectional view taken along line X1-X1′ of FIG. 1. FIG. 2B is a cross-sectional view taken along line Y1-Y1′ of FIG. 1. FIGS. 2C and 2D are each an enlarged perspective view of a partial region of the IC device 100. FIG. 2E is an enlarged cross-sectional view of portions “EX1” and “EX2” of FIG. 2A. The IC device 100 including a field-effect transistor (FET) having a gate-all-around structure including an active region of a nanowire or nanosheet type and a gate surrounding the active region will now be described with reference to FIGS. 1 and 2A to 2E.

Referring to FIGS. 1 and 2A to 2E, the IC device 100 may include a plurality of fin-type active regions F1 and a plurality of nanosheet stacks NSS. The plurality of fin-type active regions F1 may protrude from a substrate 102 and extend (i.e., have an extended length) in a first lateral direction (X direction). The plurality of nanosheet stacks NSS may be above and separate from the plurality of fin-type active regions F1 in a vertical direction (Z direction) and face fin top surfaces FT of the fin-type active regions F1. As used herein, the term “nanosheet” refers to a conductive structure having a cross-section that is substantially perpendicular to a direction in which current flows. The nanosheet may be interpreted as including a nanowire.

Trenches T1 defining the plurality of fin-type active regions F1 may be formed in the substrate 102 and filled by a device isolation film 112. The substrate 102 may include a semiconductor element, such as silicon (Si) or germanium (Ge), or a compound semiconductor, such as silicon germanium (SiGe), silicon carbide (SiC), gallium arsenide (GaAs), indium arsenide (InAs), indium gallium arsenide (InGaAs), or indium phosphide (InP). As used herein, each of the terms “SiGe,” “SiC,” “GaAs,” “InAs,” “InGaAs,” and “InP” refers to a material including elements included therein, without referring to a chemical formula representing a stoichiometric relationship. The substrate 102 may include a conductive region (e.g., a doped well) or a doped structure. The device isolation film 112 may include an oxide film, a nitride film, or a combination thereof.

A plurality of gate lines 160 may be on the plurality of fin-type active regions F1. Each of the plurality of gate lines 160 may extend in a second lateral direction (Y direction) that intersects with the first lateral direction (X direction).

The plurality of nanosheet stacks NSS may be respectively arranged on fin top surfaces FT of the plurality of fin-type active regions F1 at intersections between the plurality of fin-type active regions F1 and the plurality of gate lines 160. Each of the plurality of nanosheet stacks NSS may include at least one nanosheet. As shown in FIGS. 2A and 2B, each of the plurality of nanosheet stacks NSS may include a first nanosheet N1, a second nanosheet N2, and a third nanosheet N3, which overlap each other in the vertical direction (Z direction) on the fin-type active region F1. The first nanosheet N1, the second nanosheet N2, and the third nanosheet N3 may be at different vertical distances (Z-directional distances) from the fin top surface FT of the fin-type active region F1. Each of the plurality of gate lines 160 may surround the first nanosheet N1, the second nanosheet N2, and the third nanosheet N3, which overlap each in the vertical direction (Z direction) and are included in the nanosheet stack NSS.

Although FIG. 1 illustrates a case in which the nanosheet stack NSS has a substantially rectangular planar shape, the disclosure is not limited thereto. The nanosheet stack NSS may have various planar shapes according to a planar shape of each of the fin-type active region F1 and the gate line 160. The present embodiment pertains to a configuration in which the plurality of nanosheet stacks NSS and the plurality of gate lines 160 are formed on one fin-type active region F1, and the plurality of nanosheet stacks NSS are arranged in a line in the first lateral direction (X direction) on one fin-type active region F1. However, the number of nanosheet stacks NSS and the number of gate lines 160 on one fin-type active region F1 are not specifically limited.

Each of the first to third nanosheets N1, N2, and N3 included in the nanosheet stack NSS may include a channel region. In one or more embodiments, each of the first nanosheet N1, the second nanosheet N2, and the third nanosheet N3 may have a thickness selected in a range of about 4 nm to about 6 nm, without being limited thereto. Here, the thickness of each of the first to third nanosheets N1, N2, and N3 refers to a size of each of the first to third nanosheets N1, N2, and N3 in the vertical direction (Z direction). In one or more embodiments, the first to third nanosheets N1, N2, and N3 may have substantially the same thickness in the vertical direction (Z direction). In other embodiments, at least some of the first to third nanosheets N1, N2, and N3 may have different thicknesses in the vertical direction (Z direction).

As shown in FIG. 2A, the first to third nanosheets N1, N2, and N3 included in one nanosheet stack NSS may have substantially the same size in the first lateral direction (X direction). In other embodiments, differently from those shown in FIG. 2A, at least some of the first to third nanosheets N1, N2, and N3 included in one nanosheet stack NSS may have different sizes in the first lateral direction (X direction).

As shown in FIGS. 2A and 2B, each of the plurality of gate lines 160 may include a main gate portion 160M and a plurality of sub-gate portions 160S. The main gate portion 160M may cover a top surface of the nanosheet stack NSS and extend in the second lateral direction (Y direction). The plurality of sub-gate portions 160S may be integrally connected to the main gate portion 160M and each be arranged between two adjacent ones of the first to third nanosheets N1, N2, and N3 and between the first nanosheet N1 and the fin-type active region F1. In the vertical direction (Z direction), a thickness of each of the plurality of sub-gate portions 160S may be less than a thickness of the main gate portion 160M.

As shown in FIG. 2A, a plurality of recesses RC may be formed in the fin-type active region F1. A lowermost surface of each of the plurality of recesses RC may be at a lower vertical level than the fin top surface FT of the fin-type active region F1. As used herein, a term “vertical level” refers to a distance from a main surface of the substrate 102 in the vertical direction (Z direction or −Z direction).

As shown in FIG. 2A, a plurality of source/drain regions 130 may be inside the plurality of recesses RC. Each of the plurality of source/drain regions 130 may be adjacent to at least one gate line 160 selected from the plurality of gate lines 160. Each of the plurality of source/drain regions 130 may have surfaces facing the first to third nanosheets N1, N2, and N3 included in the nanosheet stack NSS adjacent thereto. Each of the plurality of source/drain regions 130 may be in contact with the first nanosheet N1, the second nanosheet N2, and the third nanosheet N3 included in the nanosheet stack NSS adjacent thereto.

Each of the plurality of gate lines 160 may include a metal, a metal nitride, a metal carbide, or a combination thereof. The metal may be selected from molybdenum (Mo), ruthenium (Ru), copper (Cu), and tungsten (W). The metal nitride may be selected from titanium nitride (TiN), tantalum nitride (TaN), titanium aluminum nitride (TiAlN), or a combination thereof. The metal carbide may include titanium aluminum carbide (TiAlC). However, a material included in the plurality of gate lines 160 is not limited to the examples described above.

A gate dielectric film 152 may be between the nanosheet stack NSS and the gate line 160. In one or more embodiments, the gate dielectric film 152 may have a stack structure of an interface dielectric film and a high-k dielectric film. The interface dielectric film may include a low-k dielectric material film e.g., a silicon oxide film, a silicon oxynitride film, or a combination thereof), which has a dielectric constant of about 9 or less. In one or more embodiments, the interface dielectric film may be omitted. The high-k dielectric film may include a material having a higher dielectric constant than a silicon oxide film. For example, the high-k dielectric film may have a dielectric constant of about 10 to about 25. The high-k dielectric film may include hafnium oxide, without being limited thereto.

As shown in FIGS. 2A and 2B, a top surface of each of the gate dielectric film 152 and the gate line 160 may be covered by a capping insulating pattern 168. The capping insulating pattern 168 may include a silicon nitride film.

On the substrate 102, a plurality of insulating spacers 118 may extend in the second lateral direction (Y direction) on the plurality of fin-type active regions F1 and the device isolation film 112. Both sidewalls of each of the gate line 160 and the capping insulating pattern 168 may be covered by a pair of insulating spacers 118. The insulating spacers 118 may cover both sidewalls of the main gate portion 160M on top surfaces of the plurality of nanosheet stacks NSS. The insulating spacers 118 may be separate from the gate line 160 with the gate dielectric film 152 therebetween. The insulating spacer 118 may include silicon nitride, silicon oxide, silicon carbonitride (SiCN), silicon boron nitride (SiBN), silicon oxynitride (SiON), silicon oxycarbonitride (SiOCN), silicon boron carbonitride (SiBCN), silicon oxycarbide (SiOC), or a combination thereof. As used herein, each of the terms “SiCN,” “SiBN,” “SION,” “SiOCN,” “SiBCN,” and “SiOC” refers to a material including elements included therein, without referring to a chemical formula representing a stoichiometric relationship.

The pair of insulating spacers 118 covering both sidewalls of the gate line 160 may extend in the second lateral direction (Y direction) to define a space (hereinafter, referred to as a first space), which extends in the second lateral direction (Y direction) and accommodates the gate line 160 and the capping insulating pattern 168. The gate line 160 may cover the fin-type active region F1 and the nanosheet stack NSS and extend in the second lateral direction (Y direction) in the first space defined by the pair of insulating spacers 118. The gate dielectric film 152 may be in contact with a surface of the fin-type active region F1 and a surface of each of the first to third nanosheets N1, N2, and N3 of the nanosheet stack NSS in the first space, and may be in contact with a bottom surface and both sidewalls of the gate line 160. The gate dielectric film 152 may extend in the second lateral direction (Y direction) in the first space.

A gate contact plug CB may be in the first space defined by the pair of insulating spacers 118 covering both sidewalls of the gate line 160. As shown in FIGS. 2A, 2B, 2C, and 2E, the gate contact plug CB may have a conductive bottom surface BT1 in contact with a top contact portion 160T1 of a top surface 160T of the gate line 160 in the first space. As shown in FIGS. 2A, 2B, 2C, and 2D, the capping insulating pattern 168 may include an insulating bottom surface BT2, a pair of first insulating sidewalls 168S1, and a second insulating sidewall 168S2. The insulating bottom surface BT2 may be in contact with a local top surface 160T2 adjacent to the top contact portion 160T1, of the top surface 160T of the gate line 160, in the first space. The pair of first insulating sidewalls 168S1 may be in contact with the pair of insulating spacers 118, and the second insulating sidewall 168S2 may be in contact with the gate contact plug CB.

As shown in FIGS. 2A and 2E, the conductive bottom surface BT1 of the gate contact plug CB, which is in contact with the top contact portion 160T1 of the gate line 160, may include a planar surface extending along one plane (e.g., an X-Y plane). Also, the insulating bottom surface BT2 of the capping insulating pattern 168, which is in contact with the local top surface 160T2 of the gate line 160, may include a planar surface extending along one plane (e.g., the X-Y plane).

As shown in FIGS. 2A and 2B, an insulating top surface 168T of the capping insulating pattern 168 and a conductive top surface CBT of the gate contact plug CB may extend along one plane at a constant vertical level LVT on the substrate 102. Similarly, a top surface of each of the pair of insulating spacers CB covering both sidewalls of the gate contact plug CB may extend along one plane at the constant vertical level LVT along with the insulating top surface 168T of the capping insulating pattern 168 and the conductive top surface CBT of the gate contact plug CB. As shown in FIGS. 2A and 2C, of the gate contact plug CB, both end portions of the conductive bottom surface BT1 and both end portions of the conductive top surface CBT may be in contact with the pair of insulating spacers 118 in the first lateral direction (X direction).

The gate contact plug CB may include a metal film including a single metal selected from Mo, Ru, Cu, and W. A constituent material of the gate contact plug CB may have a lower electrical resistance than a constituent material of at least a portion of the gate line 160. For example, the gate line 160 may include a metal-containing film portion including TiN, TaN, TiAlN, TiAlC, or a combination thereof, and the gate contact plug CB may include a single metal film including Mo or W. Thus, by adopting a structure in which the constituent material of the gate contact plug CB has a lower electrical resistance than that of at least the portion of the gate line 160, electrical properties of the gate contact plug CB may improve.

When the gate contact plug CB includes Mo, a conductive barrier film (e.g., a conductive barrier film including a meal nitride film) may not be between the gate contact plug CB and the pair of insulating spacers 118 covering both sidewalls of the gate contact plug CB in the first lateral direction (X direction). In addition, when the gate contact plug CB includes Mo, a conductive barrier film (e.g., a conductive barrier film including a metal nitride film) may not be between the gate contact plug CB and a pair of capping insulating patterns 168 covering both sidewalls of the gate contact plug CB in the second lateral direction (Y direction). Accordingly, by adopting a structure in which the constituent material of the gate contact plug CB has a lower electrical resistance than the constituent material of at least the portion of the gate line 160 and the gate contact plug CB does not include a metal nitride film having a relatively high electrical resistance, electrical properties of the gate contact plug CB may further improve.

In one or more embodiments, the gate line 160 may include a metal-containing film portion including TiN, TaN, TiAlN, TiAlC, or a combination thereof and a metal film portion including Mo, Ru, Cu, W, or a combination thereof. In one or more embodiments, the metal film portion of the gate line 160 and the gate contact plug CB may include the same material selected from Mo, Ru, Cu, and W and be integrally connected to each other. For example, the metal film portion of the gate line 160 and the gate contact plug CB may each include Mo and be integrally connected to each other. In other embodiments, the metal film portion of the gate line 160 and the gate contact plug CB may include the same material selected from Mo, Ru, Cu, and W, and an interface may be between the metal film portion of the gate line 160 and the gate contact plug CB. For example, the metal film portion of the gate line 160 and the gate contact plug CB may each include Mo, and an interface may be between the metal film portion of the gate line 160 and the gate contact plug CB. In still other embodiments, the metal film portion of the gate line 160 and the gate contact plug CB may include respectively different materials, which are selected from Mo, Ru, Cu, and W. For example, the metal film portion of the gate line 160 may include W, and the gate contact plug CB may include Mo.

As shown in FIG. 2A, both sidewalls of each of the plurality of sub-gate portions 160S may be separate from the source/drain region 130 with the gate dielectric film 152 therebetween. The gate dielectric film 152 may be between the sub-gate portion 160S included in the gate line 160 and each of the first to third nanosheets N1, N2, and N3 and between the sub-gate portion 160S included in the gate line 160 and the source/drain region 130.

The plurality of nanosheet stacks NSS may be respectively on fin top surfaces FT of the plurality of fin-type active regions F1 at intersections between the plurality of fin-type active regions F1 and the plurality of gate lines 160. Each of the plurality of nanosheet stacks NSS may be separate from the fin-type active region F1 and face the fin top surface FT of the fin-type active region F1. A plurality of FETs TR may be formed in portions where the plurality of fin-type active regions F1 intersect with the plurality of gate lines 160 on the substrate 102.

Although FIG. 1 illustrates a case in which the nanosheet stack NSS has a substantially rectangular planar shape, the disclosure is not limited thereto. The nanosheet stack NSS may have various planar shapes according to a planar shape of each of the fin-type active region F1 and the gate line 160. The present embodiment pertains to a configuration in which the plurality of nanosheet stacks NSS and the plurality of gate lines 160 are formed on one fin-type active region F1, and the plurality of nanosheet stacks NSS are arranged in a line in the first lateral direction (X direction) on one fin-type active region F1. However, according to the disclosure, the number of nanosheet stacks NSS on one fin-type active region F1 is not specifically limited. For example, one nanosheet stack NSS may be formed on one fin-type active region F1. The present embodiment pertains to an example in which each of the plurality of nanosheet stacks NSS includes three nanosheets, but the disclosure is not limited thereto. For example, the nanosheet stack NSS may include at least one nanosheet, and the number of nanosheets included in the nanosheet stack NSS is not specifically limited.

Each of the first to third nanosheets N1, N2, and N3 included in the nanosheet stack NSS may include a channel region. In one or more embodiments, each of the first to third nanosheets N1, N2, and N3 included in the nanosheet stack NSS may include a Si layer, a SiGe layer, or a combination thereof.

A metal silicide film 172 may be formed on a top surface of each of the plurality of source/drain regions 130. The metal silicide film 172 may be selected from titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). For example, the metal silicide film 172 may include titanium silicide, without being limited thereto.

An insulating liner 142 and an inter-gate dielectric film 144 may be sequentially arranged on the plurality of source/drain regions 130 and the plurality of metal silicide films 172. The insulating liner 142 and the inter-gate dielectric film 144 may constitute an insulating structure. The insulating spacers 118 and the plurality of source/drain regions 130 may be covered by an insulating liner 142. In one or more embodiments, the insulating liner 142 may include silicon nitride (SiN), SiCN, SiBN, SiON, SiOCN, SiBCN, or a combination thereof, without being limited thereto. The inter-gate dielectric film 144 may include a silicon oxide film, without being limited thereto. In one or more embodiments, the insulating liner 142 may be omitted. When the insulating liner 142 is omitted, the inter-gate dielectric film 144 may be in contact with the plurality of source/drain regions 130.

A plurality of source/drain contacts CA may be arranged on the plurality of source/drain regions 130. Each of the plurality of source/drain contacts CA may pass through the insulating structure including the inter-gate dielectric film 144 and the insulating liner 142 in the vertical direction (Z direction) and contact the metal silicide film 172. Each of the plurality of source/drain contacts CA may be electrically connectable to the source/drain region 130 through the metal silicide film 172. Each of the plurality of source/drain contacts CA may be separate from the main gate portion 160M with the insulating spacer 118 therebetween in the first lateral direction (X direction).

A plurality of source/drain via contacts VA may be on the plurality of source/drain contacts CA. Each of the plurality of via contacts VA may be integrally connected to a selected one of the plurality of source/drain contacts CA. The source/drain contact CA and the via contact VA, which are integrally connected to each other, may constitute a source/drain contact structure CVA. The source/drain contact structure CVA may include a conductive barrier film 174 and a contact plug 176. The conductive barrier film 174 may cover a bottom surface of the contact plug 176 and both sidewalls of the contact plug 176 in the first lateral direction (X direction). Each of the conductive barrier film 174 and the contact plug 176 may include a lower portion (a dashed region portion denoted by B1 in FIG. 2D) constituting the source/drain contact CA and an upper portion (a dashed region portion denoted by B2 in FIG. 2D) constituting the via contact VA. The lower portion and the upper portion of each of the conductive barrier film 174 and the contact plug 176 may be integrally connected to each other. The conductive barrier film 174 may be between the metal silicide film 172 and the contact plug 176. The conductive barrier film 174 may have a surface in contact with the metal silicide film 172 and a surface in contact with the contact plug 176.

As shown in FIG. 2D, a top surface of a portion of the contact plug 176, which constitutes the source/drain contact CA, and both sidewalls of a portion of the contact plug 176, which constitutes the via contact VA in the second lateral direction (Y direction), may not be covered by the conductive barrier film 174. The top surface of the portion of the contact plug 176, which constitutes the source/drain contact CA, and the both sidewalls of the portion of the contact plug 176, which constitutes the via contact VA in the second lateral direction (Y direction), may be covered by an insulating film. As shown in FIG. 2A, a top surface of the via contact VA, which forms an uppermost surface of the source/drain contact structure CVA may extend along one plane at the constant vertical level LVT on the substrate 102 together with the conductive top surface CBT of the gate contact plug CB.

In one or more embodiments, the conductive barrier film 174 in the source/drain contact structure CVA may include a metal or a metal nitride. For example, the conductive barrier film 174 may include titanium (Ti), tantalum (Ta), tungsten (W), titanium nitride (TiN), tantalum nitride (TaN), tungsten nitride (WN), tungsten carbonitride (WCN), titanium silicon nitride (TiSiN), tantalum silicon nitride (TaSiN), tungsten silicon nitride (WSiN), or a combination thereof, without being limited thereto. The contact plug 176 included in the source/drain contact structure CVA may include a metal selected from molybdenum (Mo), copper (Cu), tungsten (W), cobalt (Co), ruthenium (Ru), manganese (Mn), titanium (Ti), tantalum (Ta), aluminum (Al), and a combination thereof.

As shown in FIGS. 2A and 2B, a top surface of each of the plurality of source/drain contacts CA and a plurality of capping insulating patterns 168 may be covered by an upper insulating structure 185. The upper insulating structure 185 may include an etch stop film 186 and an interlayer insulating film 187, which are sequentially stacked on the via contact VA of the source/drain contact structure CVA and the capping insulating pattern 168. The etch stop film 186 may include silicon carbide (SiC), silicon nitride (SiN), nitrogen-doped silicon carbide (SiC:N), silicon oxycarbide (SiOC), aluminum nitride (AlN), aluminum oxynitride (AlON), aluminum oxide (AlO), aluminum oxycarbide (AlOC), or a combination thereof. The interlayer insulating film 187 may include an oxide film, a nitride film, an ultralow-k (ULK) film having an ultralow dielectric constant K of about 2.2 to about 2.4, or a combination thereof. For example, the interlayer insulating film 187 may include a tetraethylorthosilicate (TEOS) film, a high-density plasma (HDP) film, a boro-phospho-silicate glass (BPSG) film, a flowable chemical vapor deposition (FCVD) oxide film, a silicon oxynitride (SiON) film, a silicon nitride (SiN) film, a silicon oxycarbide (SiOC) film, a SiCOH film, or a combination thereof, without being limited thereto.

A plurality of upper wiring layers M1 passing through the upper insulating structure 185 may be on the substrate 102. The plurality of upper wiring layers M1 may include an upper wiring layer M1 connected to the via contact VA and an upper wiring layer M1 connected to the gate contact plug CB. The plurality of upper wiring layers M1 may include Mo, Cu, W, Co, Ru, Mn, Ti, Ta, Al, a combination thereof, or an alloy thereof, without being limited thereto.

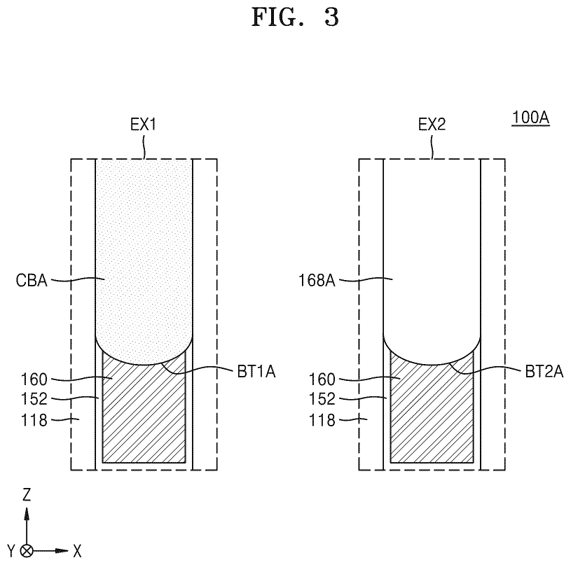

FIGS. 3, 4, 5, 6A to 6H, 7A, and 7B are respectively cross-sectional views of IC devices 100A, 200, 200A, 300A, 300B, 300C, 300D, 300E, 300F, 300G, 300H, 400A, and 400B according to one or more embodiments. FIGS. 3, 4, 5, 6A to 6H, 7A, and 7B each illustrate an enlarged cross-sectional configuration of a portion corresponding to portions “EX1” and “EX2” of FIG. 2A. In FIGS. 3, 4, 5, 6A to 6H, 7A, and 7B, the same reference numerals are used to denote the same elements as in FIGS. 1 and 2A to 2E, and repeated descriptions thereof are omitted herein.

Referring to FIG. 3, an IC device 100A may have substantially the same configuration as the IC device 100 described with reference to FIGS. 1 and 2A to 2E. However, the IC device 100A may include a gate contact plug CBA and a capping insulating pattern 168A instead of the gate contact plug CB and the capping insulating pattern 168.

The gate contact plug CBA and the capping insulating pattern 168A may respectively and have substantially the same configurations as the gate contact plug CB and the capping insulating pattern 168 described with reference to FIGS. 1 and 2A to 2E. However, with regard to the gate contact plug CBA, a conductive bottom surface BT1A in contact with a top surface of the gate line 160 may have a convex sectional shape toward a bottom surface of the gate line 160. Of the capping insulating pattern 168A, an insulating bottom surface BT2A in contact with the top surface of the gate line 160 may have a convex sectional shape toward the bottom surface of the gate line 160. The top surface of the gate line 160 may be in contact with each of the gate contact plug CBA and the capping insulating pattern 168A and have a concave cross-sectional shape toward each of the gate contact plug CBA and the capping insulating pattern 168A.

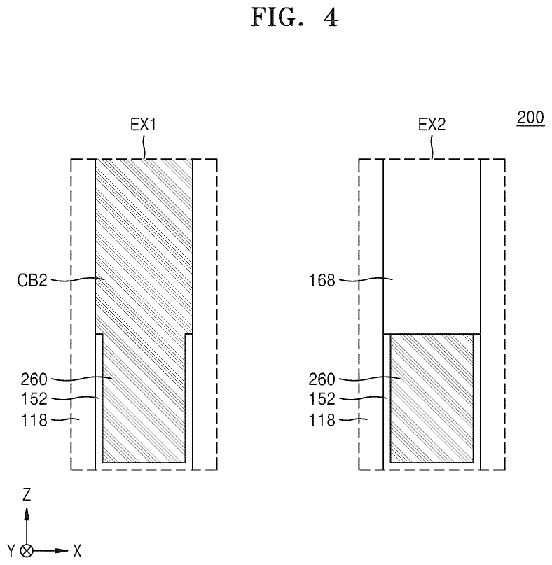

Referring to FIG. 4, an IC device 200 may have substantially the same configuration as the IC device 100 described with reference to FIGS. 1 and 2A to 2E. However, the IC device 200 may include a gate line 260 and a gate contact plug CB2 instead of the gate line 160 and the gate contact plug CB.

The gate line 260 and the gate contact plug CB2 may have substantially the same configurations as the gate line 160 and the gate contact plug CB described with reference to FIGS. 1 and 2A to 2E. However, the gate line 260 may be integrally connected to the gate contact plug CB2.

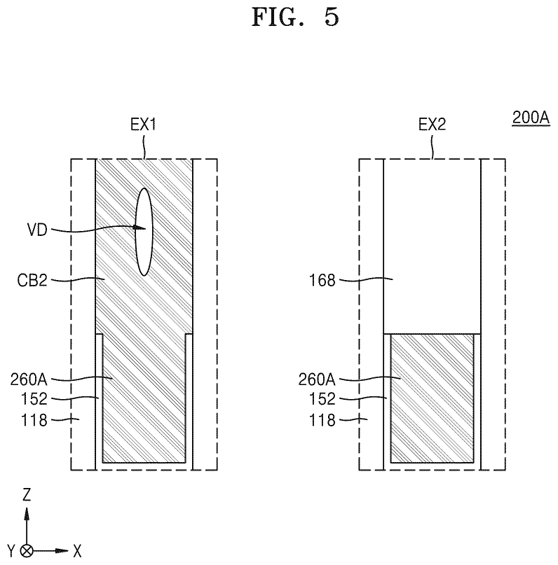

Referring to FIG. 5, an IC device 200A may have substantially the same configuration as the IC device 200 described with reference to FIG. 4. However, in the IC device 200A, a void VD may be formed in the gate contact plug CB2. The void VD may be a space formed due to the generation of a seam during a deposition process of forming the gate contact plug CB2. The void VD may include a space including the atmosphere or other gases that may be present during a manufacturing process.

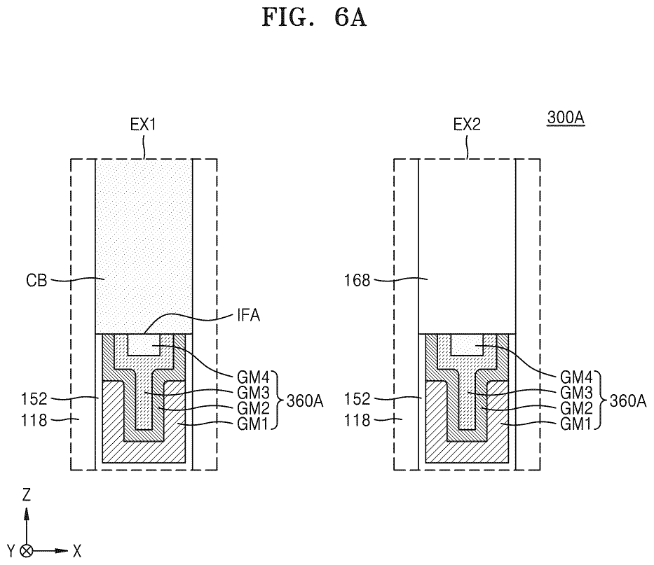

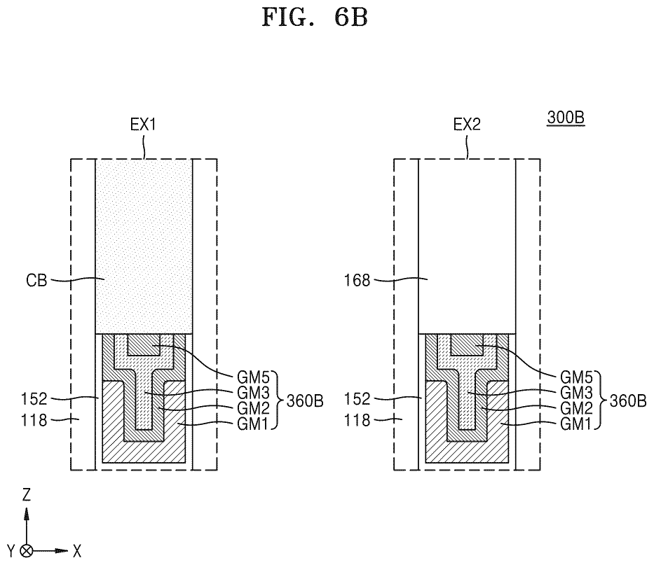

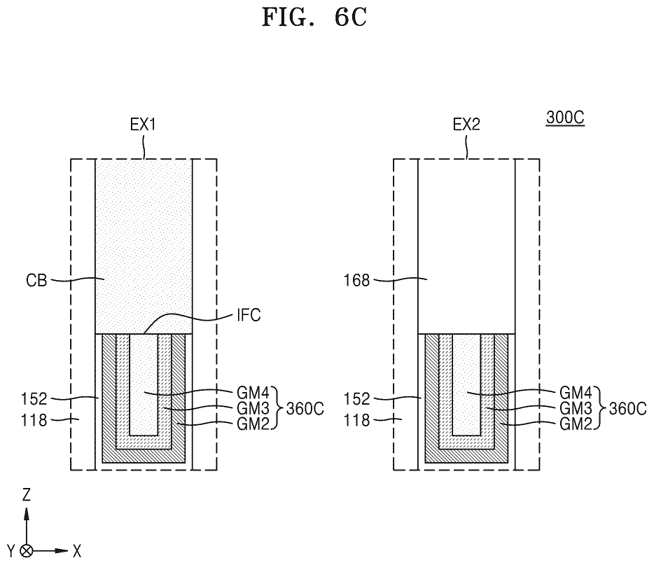

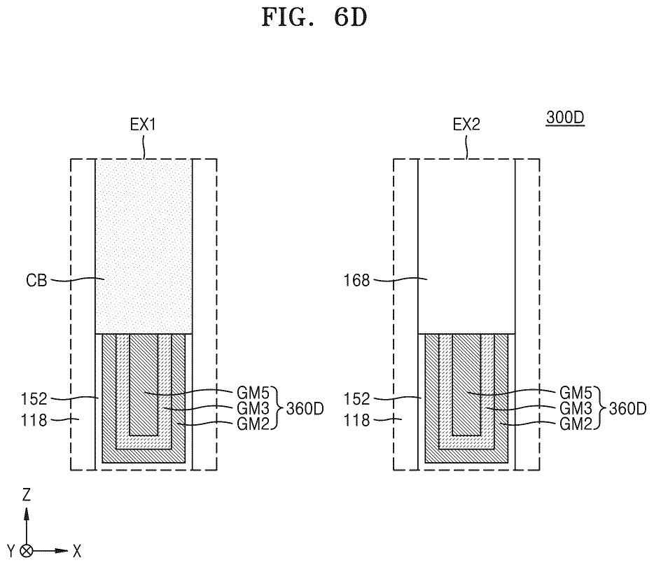

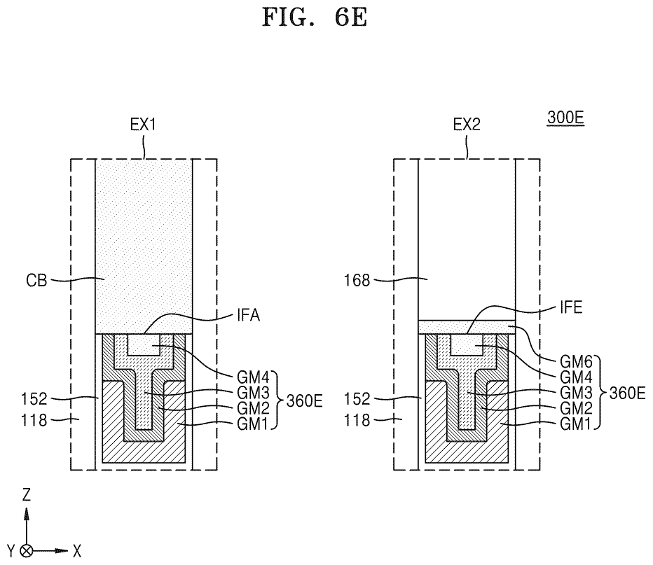

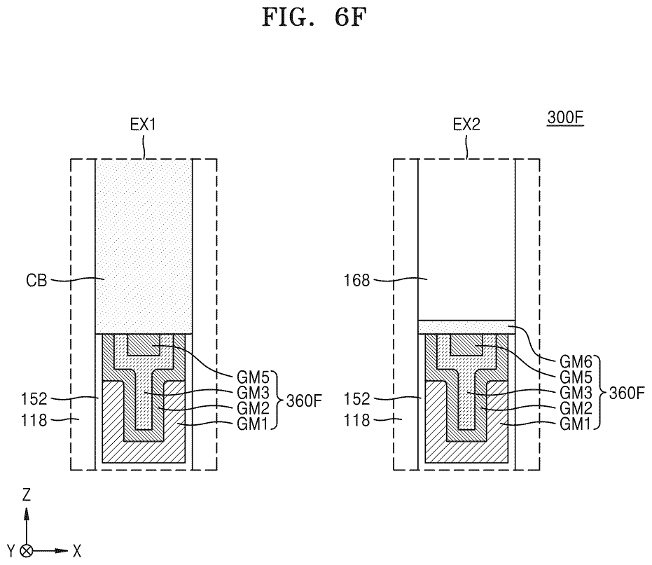

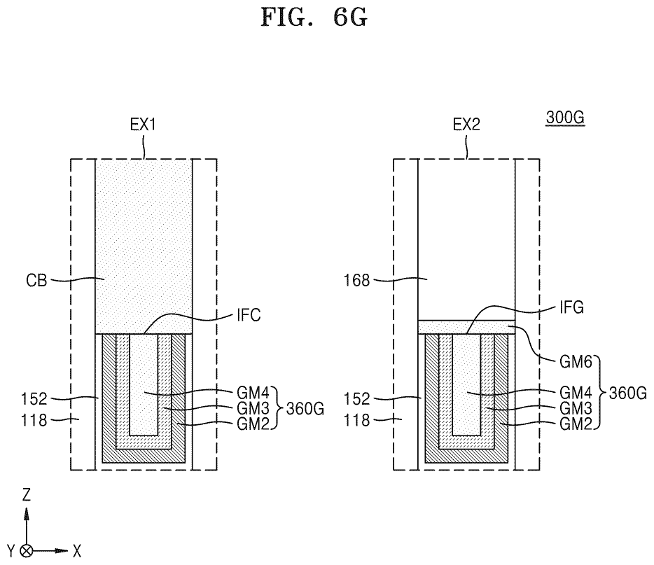

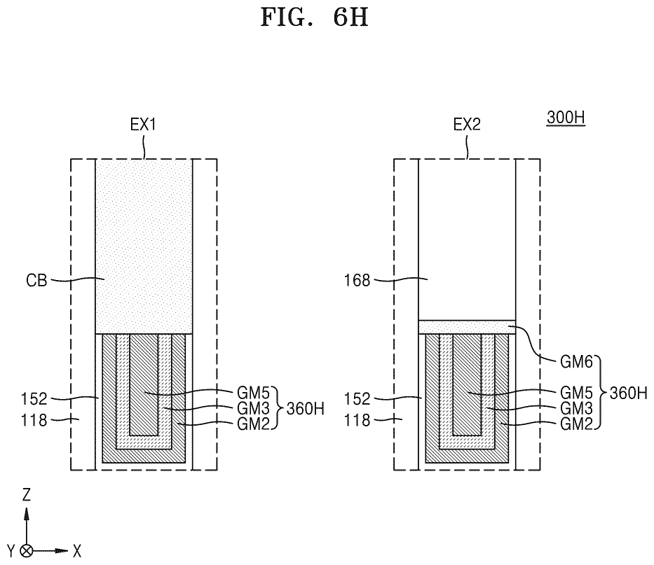

Referring to FIG. 6A, an IC device 300A may have substantially the same configuration as the IC device 100 described with reference to FIGS. 1 and 2A to 2E. However, the IC device 300A may include a gate line 360A.

The gate line 360A may have a multilayered structure in which a plurality of metal-containing films are stacked. The plurality of metal-containing films may include at least one selected from a metal, a metal nitride, and a metal carbide. In one or more embodiments, the metal may include Mo, Ru, Cu, W, or a combination thereof. The metal nitride may include TiN, TaN, TiAlN, or a combination thereof, without being limited thereto. The metal carbide may include TiAlC, without being limited thereto.

The gate line 360A may include a first metal-containing film GM1, a second metal-containing film GM2, a third metal-containing film GM3, and a fourth metal-containing film GM4, which are sequentially stacked from a lowermost surface of the gate line 360A. In one or more embodiments, the first metal-containing film GM1 may include TiAlN, the second metal-containing film GM2 may include TiN, the third metal-containing film GM3 may include TiAlC, and the fourth metal-containing film GM4 may include Mo.

In the gate line 360A, a vertical level of an uppermost surface of the first metal-containing film GM1 may be closer to the lowermost surface of the gate line 360A than a vertical level of an uppermost surface of each of the second metal-containing film GM2, the third metal-containing film GM3, and the fourth metal-containing film GM4. The uppermost surface of each of the second metal-containing film GM2, the third metal-containing film GM3, and the fourth metal-containing film GM4 may be in contact with a bottom surface of the gate contact plug CB and a bottom surface of the capping insulating pattern 168, and the uppermost surface of the first metal-containing film GM1 may be apart from the gate contact plug CB and the capping insulating pattern 168 with the second metal-containing film GM2 therebetween.

In the IC device 300A, the gate contact plug CB may include the same material as a constituent material of the fourth metal-containing film GM4 of the gate line 360A. The gate contact plug CB may include a material having a lower electrical resistance than a constituent material included in each of the first metal-containing film GM1, the second metal-containing film GM2, and the third metal-containing film GM3 included in the gate line 350. For example, the gate contact plug CB may include Mo. The fourth metal-containing film GM4 and the gate contact plug CB may each include Mo. Here, the fourth metal-containing film GM4 and the gate contact plug CB may include the same material, but formed using different processes from each other, and an interface IFA may be between the fourth metal-containing film GM4 and the gate contact plug CB.

Referring to FIG. 6B, an IC device 300B may have substantially the same configuration as the IC device 100 described with reference to FIGS. 1 and 2A to 2E. However, the IC device 300B may include a gate line 360B.

The gate line 360B may have substantially the same configuration as the gate line 360A described with reference to FIG. 6A. However, the gate line 360B may not include a metal included in the gate contact plug CB.

The gate line 360B may include a first metal-containing film GM1, a second metal-containing film GM2, a third metal-containing film GM3, and a fifth metal-containing film GM5, which are sequentially stacked on a lowermost surface of the gate line 360B. In one or more embodiments, the first metal-containing film GM1 may include TiAlN, the second metal-containing film GM2 may include TiN, the third metal-containing film GM3 may include TiAlC, and the fifth metal-containing film GM5 may include TiN.

Details of the first metal-containing film GM1, the second metal-containing film GM2, and the third metal-containing film GM3 are the same as those described with reference to FIG. 6A. The gate contact plug CB may include a material having a lower electrical resistance than a constituent material of at least some of the first metal-containing film GM1, the second metal-containing film GM2, the third metal-containing film GM3, and the fifth metal-containing film GM5 included in the gate line 360B. In the IC device 300B, the gate contact plug CB may include a different material from a constituent material of the fifth metal-containing film GM5 of the gate line 360B. For example, the gate contact plug CB may include Mo, and the fourth metal-containing film GM4 may include TiN.

Referring to FIG. 6C, an IC device 300C may have substantially the same configuration as the IC device 100 described with reference to FIGS. 1 and 2A to 2E. However, the IC device 300C may include a gate line 360C.

The gate line 360C may have substantially the same configuration as the gate line 360A described with reference to FIG. 6A. The gate line 360C may have a multilayered structure in which a plurality of metal-containing films are stacked. However, an uppermost surface of each of the plurality of metal-containing films included in the gate line 360C may be in contact with a bottom surface of the gate contact plug CB and a bottom surface of the capping insulating pattern 168.

The gate line 360C may include a second metal-containing film GM2, a third metal-containing film GM3, and a fourth metal-containing film GM4, which are sequentially stacked on a lowermost surface of the gate line 360C. In one or more embodiments, the second metal-containing film GM2 may include TiN, the third metal-containing film GM3 may include TiAlC, and the fourth metal-containing film GM4 may include Mo.

In the IC device 300C, the gate contact plug CB may include the same material as a constituent material of the fourth metal-containing film GM4 of the gate line 360C. The gate contact plug CB may include a material having a lower electrical resistance than a constituent material of each of the second metal-containing film GM2 and the third metal-containing film GM3 included in the gate line 360C. In the IC device 300C, the fourth metal-containing film GM4 and the gate contact plug CB may each include Mo. The fourth metal-containing film GM4 and the gate contact plug CB may include the same material, but formed using different processes from each other, and an interface IFC may be between the fourth metal-containing film GM4 and the gate contact plug CB.

Referring to FIG. 6D, an IC device 300D may have substantially the same configuration as the IC device 100 described with reference to FIGS. 1 and 2A to 2E.

However, the IC device 300D may include a gate line 360D.

The gate line 360D may have substantially the same configuration as the IC device 360C described with reference to FIG. 6C. However, the gate line 360D may include a fifth metal-containing film GM5 instead of the fourth metal-containing film GM4. In one or more embodiments, the fifth metal-containing film GM5 may include TiN. An uppermost surface of each of a second metal-containing film GM2, a third metal-containing film GM3, and the fifth metal-containing film GM5 included in the gate line 360D may be in contact with a bottom surface of the gate contact plug CB and a bottom surface of the capping insulating pattern 168.

Referring to FIG. 6E, an IC device 300E may have substantially the same configuration as the IC device 300A described with reference to FIG. 6A. However, the IC device 300A may include a gate line 360E.

The gate line 360E may have substantially the same configuration as the gate line 360A described with reference to FIG. 6A. However, the gate line 360E may further include a sixth metal-containing film GM6 between each of a second metal-containing film GM2, a third metal-containing film GM3, and a fourth metal-containing film GM4 and a capping insulating pattern 168. A constituent material of the sixth metal-containing film GM6 may be the same as that of the gate contact plug CB. In one or more embodiments, the fourth metal-containing film GM4, the sixth metal-containing film GM6, and the gate contact plug CB may each include Mo. An interface IFA may be between the fourth metal-containing film GM4 and the gate contact plug CB, and an interface IFE may be between the fourth metal-containing film GM4 and the sixth metal-containing film GM6.

Referring to FIG. 6F, an IC device 300F may have substantially the same configuration as the IC device 300B described with reference to FIG. 6B. However, the IC device 300F may include a gate line 360F.

The gate line 360F may have substantially the same configuration as the gate line 360B described with reference to FIG. 6B. However, the gate line 360F may further include a sixth metal-containing film GM6 between each of a second metal-containing film GM2, a third metal-containing film GM3, and a fifth metal-containing film GM5 and the capping insulating pattern 168. Details of the sixth metal-containing film GM6 are the same as those described with reference to FIG. 6E.

Referring to FIG. 6G, an IC device 300G may have substantially the same configuration as the IC device 300C described with reference to FIG. 6C. However, the IC device 300G may include a gate line 360G.

The gate line 360G may have substantially the same configuration as the gate line 360C described with reference to FIG. 6C. However, the gate line 360G may further include a sixth metal-containing film GM6 between each of a second metal-containing film GM2, a third metal-containing film GM3, and a fourth metal-containing film GM4 and a capping insulating pattern 168. A constituent material of the sixth metal-containing film GM6 may be the same as that of a gate contact plug CB. In one or more embodiments, each of the fourth metal-containing film GM4, the sixth metal-containing film GM6, and the gate contact plug CB may include Mo. An interface IFC may be between the fourth metal-containing film GM4 and the gate contact plug CB, and an interface IFG may be between the fourth metal-containing film GM4 and the sixth metal-containing film GM6.

Referring to FIG. 6H, an IC device 300H may have substantially the same configuration as the IC device 300D described with reference to FIG. 6D. However, the IC device 300H may include a gate line 360H.

The gate line 360H may have substantially the same configuration as the gate line 360D described with reference to FIG. 6D. However, the gate line 360H may further include a sixth metal-containing film GM6 between each of a second metal-containing film GM2, a third metal-containing film GM3, and a fifth metal-containing film GM5 and a capping insulating pattern 168. Details of the sixth metal-containing film GM6 are the same as those described with reference to FIG. 6E.

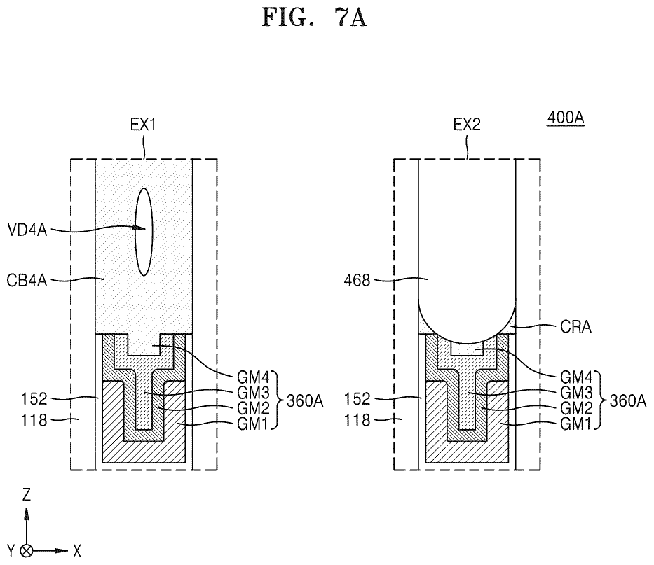

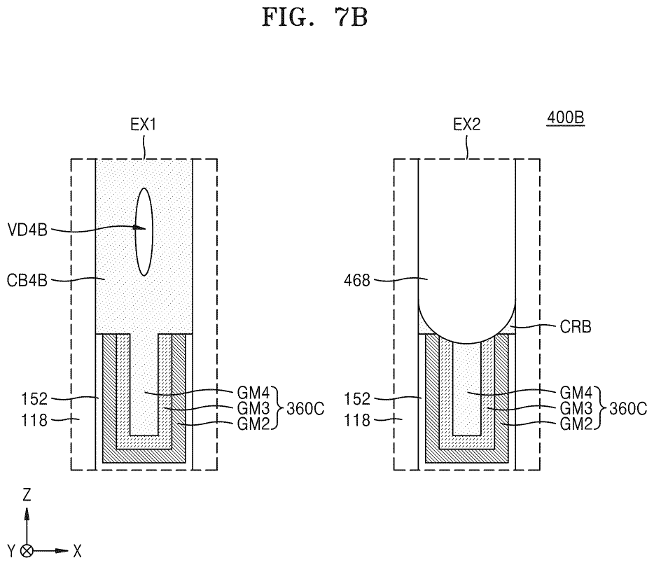

Referring to FIG. 7A, an IC device 400A may have substantially the same configuration as the IC device 300A described with reference to FIG. 6A. However, the IC device 400A may include a gate contact plug CB4A and a capping insulating pattern 468. The gate contact plug CB4A may have substantially the same configuration as the gate contact plug CB described with reference to FIG. 6A. However, a fourth metal-containing film GM4 of a gate line 360A and the gate contact plug CB4A may include the same material as each other and be integrally connected to each other. A void VD4A may be inside the gate contact plug CB4A. The void VD4A may be a space formed due to the generation of a seam during a deposition process of forming the fourth metal-containing film GM4 and the gate contact plug CB4A. The void VD4A may include a space including the atmosphere or other gases that may be present during a manufacturing process.

The capping insulating pattern 468 may have substantially the same configuration as the capping insulating pattern 168 shown in FIG. 6A. However, the capping insulating pattern 468 may have a convex sectional shape toward a bottom surface of the gate line 360A.

In the IC device 400A, a residual metal film CRA may be in a corner region defined by an uppermost surface of each of a gate dielectric film 152 and the gate line 360A and a bottom surface of the capping insulating pattern 468. The residual metal film CRA may be intermittently in the corner region. In a local region adjacent to the gate contact plug CB4A, the residual metal film CRA may be integrally connected to the gate contact plug CB4A. However, in a region separate from the gate contact plug CB4A, the residual metal film CRA may not be connected to the gate contact plug CB4A but may be separate from the gate contact plug CB4A. The residual metal film CRA may include the same constituent material as the gate contact plug CB4A. For example, the residual metal film CRA and the gate contact plug CB4A may include Mo.

Referring to FIG. 7B, an IC device 400B may have substantially the same configuration as the IC device 300C described with reference to FIG. 6C. However, the IC device 400B may include a gate contact plug CB4B and a capping insulating pattern 468. The gate contact plug CB4B may have substantially the same configuration as the gate contact plug CB shown in FIG. 6C. However, a fourth metal-containing film GM4 of a gate line 360C and the gate contact plug CB4B may include the same material as each other and be integrally connected to each other. A void VD4B may be inside the gate contact plug CB4B. The void VD4B may be a space formed during a process of forming the fourth metal-containing film GM4 and the gate contact plug CB4B. The void VD4B may include a space including the atmosphere or other gases that may be present during a manufacturing process.

In the IC device 400B, a residual metal film CRB may be in a corner region defined by an uppermost surface of each of a gate dielectric film 152 and the gate line 360C and a bottom surface of the capping insulating pattern 468. The residual metal film CRB may be intermittently in the corner region. In a local region adjacent to the gate contact plug CB4B, the residual metal film CRB may be integrally connected to the gate contact plug CB4B. However, in a region separate from the gate contact plug CB4B, the residual metal film CRB may not be connected to the gate contact plug CB4B but be separate from the gate contact plug CB4A. The residual metal film CRB may include the same constituent material as the gate contact plug CB4B. For example, the residual metal film CRB and the gate contact plug CB4B may include Mo.

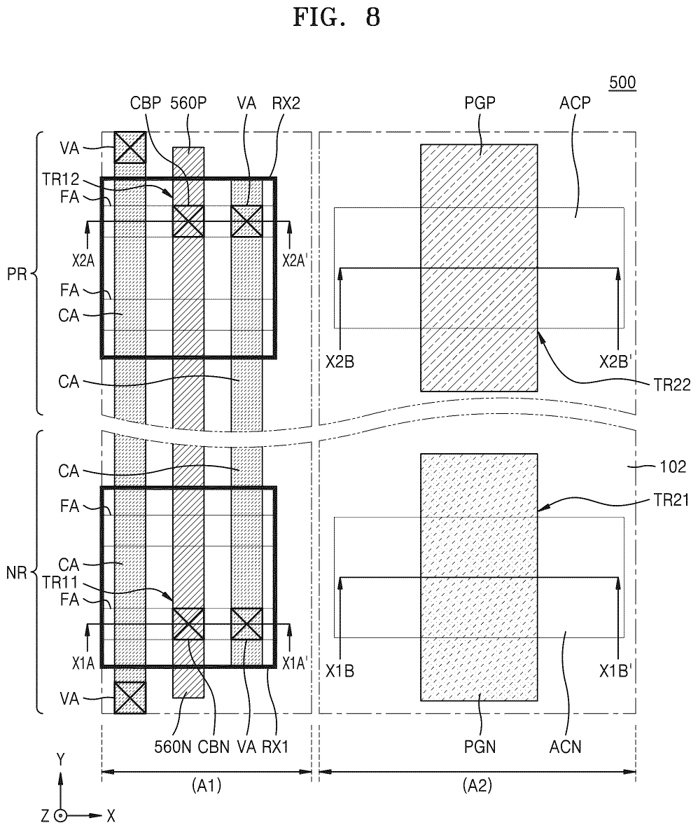

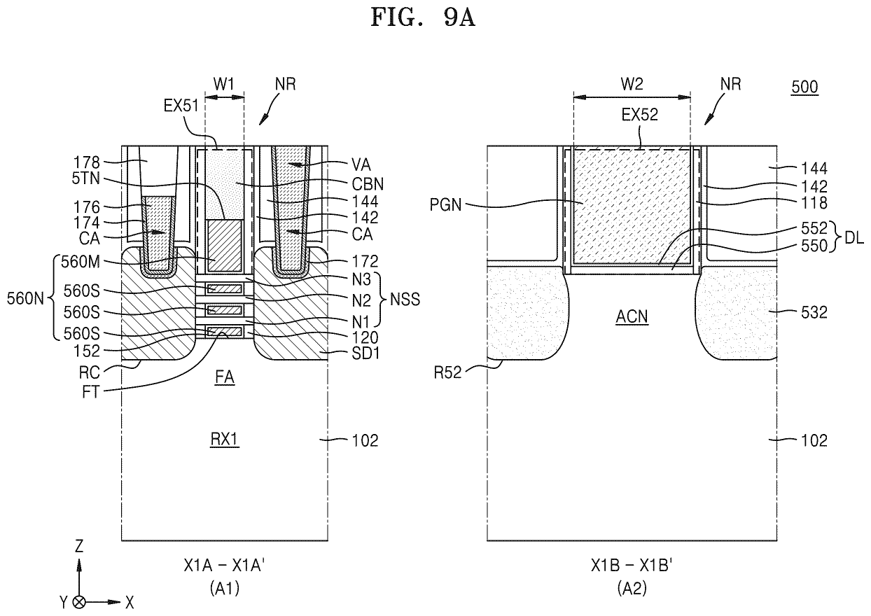

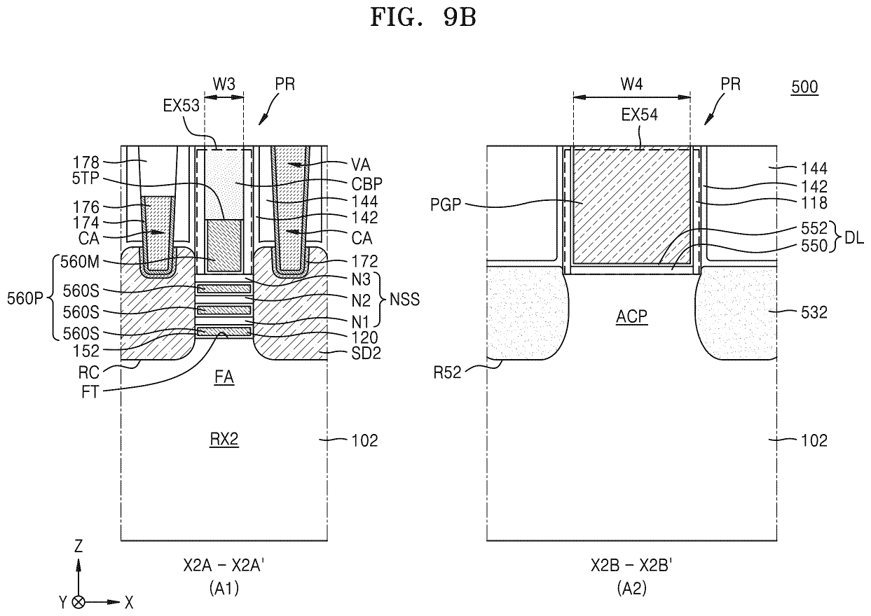

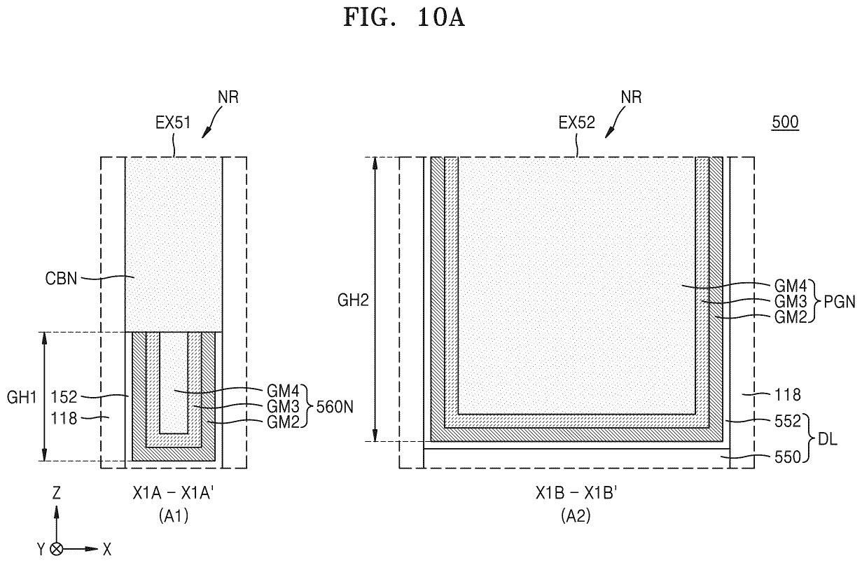

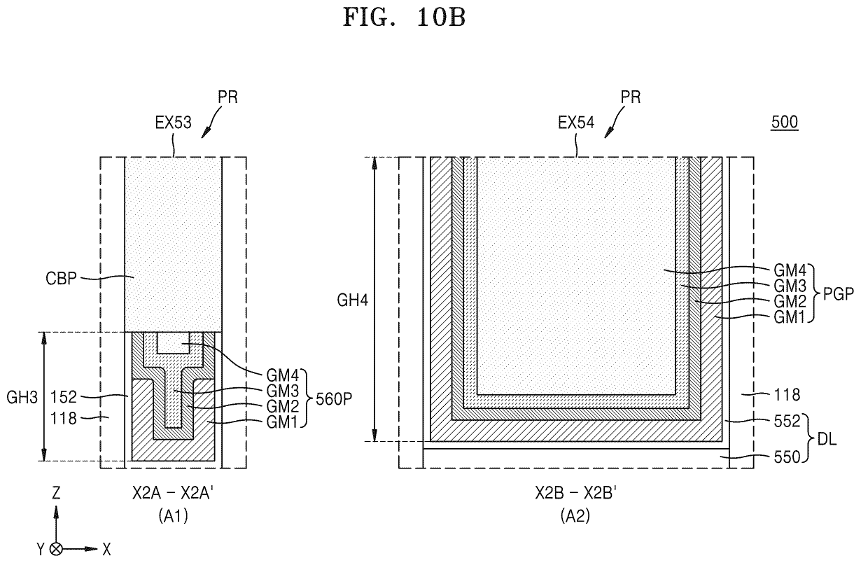

FIG. 8 is a plan layout diagram of some components of an IC device 500 according to one or more embodiments. FIG. 9A is a cross-sectional view of some components corresponding to each of a cross-section taken along line X1A-X1A′ and a cross-section taken along line X1B-X1B′ of FIG. 8, and FIG. 9B is a cross-sectional view of some components corresponding to each of a cross-section taken along line X2A-X2A′ and a cross-section taken along line X2B-X2B′ of FIG. 8. FIG. 10A is an enlarged cross-sectional view of portions “EX51” and “EX52” of FIG. 9A. FIG. 10B is an enlarged cross-sectional view of portions “EX53” and “EX54” of FIG. 9B. In FIGS. 8, 9A, 9B, 10A, and 10B, the same reference numerals are used to denote the same elements as in FIGS. 1 and 2A to 2E, and repeated descriptions thereof are omitted here.

Referring to FIGS. 8, 9A, 9B, 10A, and 10B, in the IC device 500, a substrate 102 may include a first device region A1 and a second device region A2, which are separate from each other in a lateral direction.

In one or more embodiments, the first device region A1 and the second device region A2 may be regions that perform different functions from each other. In other embodiments, the first device region A1 and the second device region A2 may include devices having different operation modes. For example, the first device region A1 may be a region in which devices operating in relatively low power modes are formed, and the second device region A2 may be a region in which devices operating in relatively high power modes are formed.

A plurality of nanosheet transistors (e.g., TR11 and TR12) may be in the first device region A1. A plurality of transistors (e.g., TR21 and TR22) may be in the second device region A2. The plurality of nanosheet transistors (e.g., TR11 and TR12) in the first device region A1 may be low-voltage transistors, which require high-speed operations and have relatively low operating voltages. The plurality of transistors (e.g., TR21 and TR22) in the second device region A2 may be high-voltage transistors configured to generate high voltages or transmit high voltages. In an example, the plurality of nanosheet transistors (e.g., TR11 and TR12) may be transistors having a relatively low operating voltage of at least about 0.5 V and less than about 10 V, and the plurality of transistors (e.g., TR21 and TR22) may be transistors having a relatively high operating voltage of at least 10 V. However, a range of an operating voltage of each of the plurality of nanosheet transistors (e.g., TR11 and TR12) and the plurality of transistors (e.g., TR21 and TR22) is not limited to the above-described example, and the operating voltage of each of the plurality of transistors (e.g., TR21 and TR22) may be variously selected within a greater range than the operating voltage of each of the plurality of nanosheet transistors (e.g., TR11 and TR12). As used herein, the first device region A1 may be referred to as a low-voltage transistor region, and the second device region A2 may be referred to as a high-voltage transistor region.

In still other embodiments, the first device region A1 may be a region in which a logic circuit or a memory device is formed, and the second device region A2 may be a region in which a peripheral circuit (e.g., an input/output (I/O) device) is formed.

Each of the first device region A1 and the second device region A2 may include an N-type metal-oxide-semiconductor (NMOS) transistor region NR and a P-type metal-oxide-semiconductor (PMOS) transistor region PR. The nanosheet transistor TR11 in a local region RX1 of the NMOS transistor region NR of the first device region A1 may be an NMOS transistor, and the nanosheet transistor TR12 in a local region RX2 of the PMOS transistor region PR of the first device region A1 may be a PMOS transistor. The nanosheet transistor TR21 in the NMOS transistor region NR of the second device region A2 may be an NMOS transistor, and the nanosheet transistor TR22 in the PMOS transistor region PR of the second device region A2 may be a PMOS transistor.

In the first device region A1, each of the NMOS transistor region NR and the PMOS transistor region PR may include a plurality of fin-type active regions FA protruding from the substrate 102. The plurality of fin-type active regions FA may have substantially the same configuration as the plurality of fin-type active regions F1 described with reference to FIGS. 1, 2A, and 2B.

A plurality of gate lines (e.g., 560N and 560P) may extend in a second lateral direction (Y direction) on the plurality of fin-type active regions FA. Each of the plurality of gate lines (e.g., 560N and 560P) may include a main gate portion 560M and a plurality of sub-gate portions 560S. Each of the plurality of gate lines (e.g., 560N and 560P) may have substantially the same configuration as the gate line 160 described with reference to FIGS. 1, 2A, and 2B. However, the gate line 560N in the NMOS transistor region NR and the gate line 560P in the PMOS transistor region PR may have different stack structures from each other. As used herein, each of the plurality of gate lines (e.g., 560N and 560P) may be referred to as a first gate line.

A plurality of nanosheet stacks NSS may be respectively on the fin top surfaces FT of the plurality of fin-type active regions FA at intersections between the plurality of fin-type active regions FA and the plurality of gate lines (e.g., 560N and 560P). Each of the plurality of nanosheet stacks NSS may be separate from the fin-type active region FA in a vertical direction (Z direction) and face the fin top surface FT of the fin-type active region FA. The plurality of gate lines (e.g., 560N and 560P) may cover the nanosheet stack NSS on the fin-type active region FA and surround each of a first nanosheet N1, a second nanosheet N2, and a third nanosheet N3. A gate dielectric film 152 may be between the nanosheet stack NSS and the gate lines 560N and 560P. The gate dielectric film 152 may cover bottom surfaces of the gate lines 560N and 560P and both sidewalls of the gate lines 560N and 560P in a first lateral direction (X direction) and extend in the second lateral direction (Y direction).

A plurality of first source/drain regions SD1 may be formed inside a plurality of recesses RC in the NMOS transistor region NR of the first device region A1, and a plurality of second source/drain regions SD2 may be formed inside a plurality of recesses RC in the PMOS transistor region PR of the first device region A1. Between two adjacent ones of the first to third nanosheets N1, N2, and N3 and between the fin-type active region FA and the first nanosheet N1 in the NMOS transistor region NR, a plurality of inner insulating spacers 120 may be between the plurality of sub-gate portions 560S and the first source/drain region SD1. In the NMOS transistor region NR of the first device region A1, both sidewalls of each of the plurality of sub-gate portions 560S may be covered by the inner insulating spacers 120 with the gate dielectric film 152 therebetween. Each of the plurality of sub-gate portions 560S may be separate from the first source/drain region SD1 with the gate dielectric film 152 and the inner insulating spacer 120 therebetween. Each of the plurality of inner insulating spacers 120 may be in contact with the first source/drain region SD1. The inner insulating spacer 120 may include silicon nitride, silicon oxide, SiCN, SiBN, SION, SiOCN, SiBCN, SiOC, or a combination thereof. The inner insulating spacer 120 may further include an air gap. In one or more embodiments, the plurality of inner insulating spacers 120 may be omitted.

In the first device region A1, both sidewalls of the plurality of gate lines (e.g., 560N and 560P) may be covered by a plurality of insulating spacers 118 on the plurality of fin-type active regions FA. The plurality of insulating spacers 118 may cover both sidewalls of the main gate portions 560M on top surfaces of the plurality of nanosheet stacks NSS. Each of the plurality of insulating spacers 118 may be separate from the gate lines 560N and 560P with the gate dielectric film 152 therebetween.

As shown in FIG. 9B, in the PMOS transistor region PR, both sidewalls of each of the plurality of sub-gate portions 560S may be separate from the second source/drain region SD2 with the gate dielectric film 152 therebetween. The gate dielectric film 152 may include a portion in contact with the second source/drain region SD2. Each of the plurality of second source/drain regions SD2 may face the nanosheet stack NSS and the plurality of sub-gate portions 560S in the first lateral direction (X direction).

In the NMOS transistor region NR, a gate contact plug CBN may be in a space defined by a pair of insulating spacers 118 covering both sidewalls of the gate line 560N. In the PMOS transistor region PR, a gate contact plug CBP may be in a space defined by a pair of insulating spacers 118 covering both sidewalls of the gate line 560P. The gate contact plugs CBN and CBP may have substantially the same configuration as the gate contact plug CB described with reference to FIGS. 2A, 2B, 2C, and 2E. Similar to the gate contact plug CB described with reference to FIGS. 2A, 2B, 2C, and 2E, the gate contact plugs CBN and CBP may have conductive bottom surfaces in contact with top contact portions 5TN and 5TP of top surfaces of the gate lines 560N and 560P. Both sidewalls of the gate lines 560N and 560P in the second lateral direction (Y direction) may be covered by a capping insulating pattern. The capping insulating pattern may have substantially the same configuration as the capping insulating pattern 168 described with reference to FIGS. 2A, 2B, 2C, and 2E. The capping insulating pattern may have an insulating bottom surface in contact with local top surfaces adjacent to the top contact portions 5TN and 5TP, of the top surfaces of the gate lines 560N and 560P, and an insulating sidewall in contact with the gate contact plugs CBN and CBP.

The gate line 560N in the NMOS transistor region NR may include a metal nitride film and a metal carbide film, which are sequentially stacked on the gate dielectric film 152. A conductive bottom surface of the gate contact plug CBN may be in contact with an uppermost surface of each of the metal nitride film and the metal carbide film. The gate contact plug CBN may include a metal film having a lower electrical resistance than a constituent material of each of the metal nitride film and the metal carbide film included in the gate line 560N. In one or more embodiments, as shown in FIG. 10A, the gate line 560N in the NMOS transistor region NR may include a second metal-containing film GM2, a third metal-containing film GM3, and a fourth metal-containing film GM4, which are sequentially stacked on a lowermost surface of the gate line 560N. The second metal-containing film GM2 may include TiN, the third metal-containing film GM3 may include TiAlC, and the fourth metal-containing film GM4 may include Mo. The gate contact plug CBN may include Mo.

The gate line 560P in the PMOS transistor region PR may include a first metal nitride film, a second metal nitride film, and a metal carbide film, which are sequentially stacked on the gate dielectric film 152. A conductive bottom surface of the gate contact plug CBP may be in contact with an uppermost surface of each of the first metal nitride film, the second metal nitride film, and the metal carbide film. The gate contact plug CBP may include a metal film having a lower electrical resistance than a constituent material of each of the first metal nitride film, the second metal nitride film, and the metal carbide film included in the gate line 560P. In one or more embodiments, as shown in FIG. 10B, the gate line 560P in the PMOS transistor region PR may include a first metal-containing film GM1, a second metal-containing film GM2, a third metal-containing film GM3, and a fourth metal-containing film GM4, which are sequentially stacked on a lowermost surface of the gate line 560P. The first metal-containing film GM1 may include TiAlN, the second metal-containing film GM2 may include TiN, the third metal-containing film GM3 may include TiAlC, and the fourth metal-containing film GM4 may include Mo. The gate contact plug CBP may include Mo.

In the NMOS transistor region NR and the PMOS transistor region PR of the first device region A1, a source/drain contact CA and a via contact VA, which are integrally connected to each other, may be on the first and second source/drain regions SD1 and SD2. A top surface of the source/drain contact CA, which is not covered by the via contact VA, may be covered by an insulating pattern 178. A sidewall of the via contact VA and a sidewall of the insulating pattern 178, which face each other in the second lateral direction (Y direction), may be in contact with each other. A metal silicide film 172 may be between the first and second source/drain regions SD1 and SD2 and the source/drain contact CA. The source/drain contact CA may be electrically connectable to the first and second source/drain regions SD1 SD2 through the metal silicide film 172. Details of the source/drain contact CA and the via contact VA, which are integrally connected to each other, are the same as those described with reference to FIGS. 2A and 2D.

In the second device region A2 of the IC device 500, a plurality of active regions ACN and ACP may be defined by a plurality of recesses R52 formed in the substrate 102. A plurality of source/drain regions 532 may be formed on the plurality of recesses R52.

A gate line PGN may be on the active region ACN in the NMOS transistor region NR of the second device region A2, and a gate line PGP may be on the active region ACP in the PMOS transistor region PR of the second device region A2. In the second device region A2, the gate line PGN in the NMOS transistor region NR and the gate line PGP in the PMOS transistor region PR may have different stack structures from each other. As used herein, the gate lines PGN and PGP in the second device region A2 may be referred as second gate lines.

In the first device region A1, the gate line 560N may have a first width W1 in the first lateral direction (X direction). In the second device region A2, the gate line PGN may have a second width W2, which is greater than the first width W1, in the same direction as a channel direction in the active region ACN. The gate line 560N in the first device region A1 and the gate PGN in the second device region A2 may have different stack structures from each other.

In the first device region A1, the gate line 560P may have a third width W3 in the first lateral direction (X direction). In the second device region A2, the gate line PGP may have a fourth width W4, which is greater than the third width W3, in the same direction as a channel direction in the active region ACP. The gate line 560P in the first device region A1 and the gate line PGP in the second device region A2 may have different stack structures from each other.

In one or more embodiments, as shown in FIG. 10A, the gate line PGN in the NMOS transistor region NR of the second device region A2 may include a second metal-containing film GM2, a third metal-containing film GM3, and a fourth metal-containing film GM4, which are sequentially stacked on a lowermost surface of the gate line PGN. The fourth metal-containing film GM4 may include a different constituent material from each of the second metal-containing film GM2 and the third metal-containing film GM3. The fourth metal-containing film GM4 may include a single metal film. A bottom surface and sidewalls of the fourth metal-containing film GM4 may be covered by the second metal-containing film GM2 and the third metal-containing film GM3.

In one or more embodiments, as shown in FIG. 10B, the gate line PGP in the PMOS transistor region PR of the second device region A2 may include a first metal-containing film GM1, a second metal-containing film GM2, a third metal-containing film GM3, and a fourth metal-containing film GM4, which are sequentially stacked on a lowermost surface of the gate line PGP. The fourth metal-containing film GM4 may include a different constituent material from each of the first metal-containing film GM1, the second metal-containing film GM2, and the third metal-containing film GM3. The fourth metal-containing film GM4 may include a single metal film. A bottom surface and sidewalls of the fourth metal-containing film GM4 may be covered by the first metal-containing film GM1, the second metal-containing film GM2, and the third metal-containing film GM3.

In the second device region A2, a gate dielectric film DL may be between the active regions ACN and ACP and the gate lines PGN and PGP. The gate dielectric film DL may include a lower gate dielectric film 550 covering the active regions ACN and ACP and an upper gate dielectric film 552 that are separate from the active regions ACN and ACP with the lower gate dielectric film 550 therebetween and in contact with the gate lines PGN and PGP. In one or more embodiments, the lower gate dielectric film 550 may include a low-k material film having a dielectric constant of about 9 or less, for example, a silicon oxide film, a silicon oxynitride film, or a combination thereof. The upper gate dielectric film 552 may have substantially the same configuration as the gate dielectric film 152 described with reference to FIGS. 2A and 2B.

In the configuration shown in FIG. 10A, a material included in a top surface of the gate contact plug CBN in the NMOS transistor region NR of the first device region A1 may be the same as a material included in a top surface of the gate line PGN in the NMOS transistor region NR of the second device region A2. For example, each of the gate contact plug CBN and the fourth metal-containing film GM4 of the gate line PGN may include Mo, and a top surface of each of the gate contact plug CBN and the fourth metal-containing film GM4 may include Mo.

In the configuration shown in FIG. 10B, a material included in a top surface of the gate contact plug CBP in the PMOS transistor region PR of the first device region A1 may be the same as a material included in a top surface of the gate line PGP in the PMOS transistor region PR of the second device region A2. For example, each of the gate contact plug CBP and the fourth metal-containing film GM4 of the gate line PGP may include Mo, and a top surface of each of the gate contact plug CBP and the fourth metal-containing film GM4 may include Mo.

As shown in FIG. 10A, a first vertical distance GH1 from an uppermost surface of each of a plurality of metal-containing films (i.e., the second metal-containing film GM2, the third metal-containing film GM3, and the fourth metal-containing film GM4) included in the gate line 560N in the NMOS transistor region NR of the first device region A1 to the lowermost surface of the gate line 560N may be less than a second vertical distance GH2 from an uppermost surface of each of a plurality of metal-containing films (i.e., the second metal-containing film GM2, the third metal-containing film GM3, and the fourth metal-containing film GM4) included in the gate line PGN in the NMOS transistor region NR of the second device region A2 to the lowermost surface of the gate line PGN.

As shown in FIG. 10B, a third vertical distance GH3 from an uppermost surface of each of a plurality of metal-containing films (i.e., the first metal-containing film GM1, the second metal-containing film GM2, the third metal-containing film GM3, and the fourth metal-containing film GM4) included in the gate line 560P in the PMOS transistor region PR of the first device region A1 to the lowermost surface of the gate line 560P may be less than a fourth vertical distance GH4 from an uppermost surface of each of a plurality of metal-containing films (i.e., the first metal-containing film GM1, the second metal-containing film GM2, the third metal-containing film GM3, and the fourth metal-containing film GM4) included in the gate line PGP in the PMOS transistor region PR of the second device region A2 to the lowermost surface of the gate line PGP.

In the second device region A2, both sidewalls of the gate lines PGN and PGP may be covered by a pair of insulating spacers 118. The gate lines PGN and PGP may be separate from the pair of insulating spacers 118 with the upper gate dielectric film 552 therebetween.

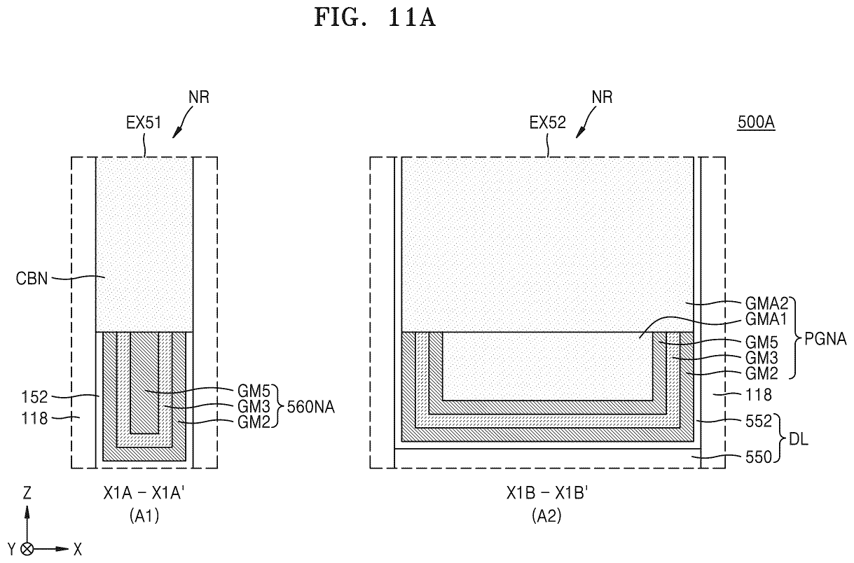

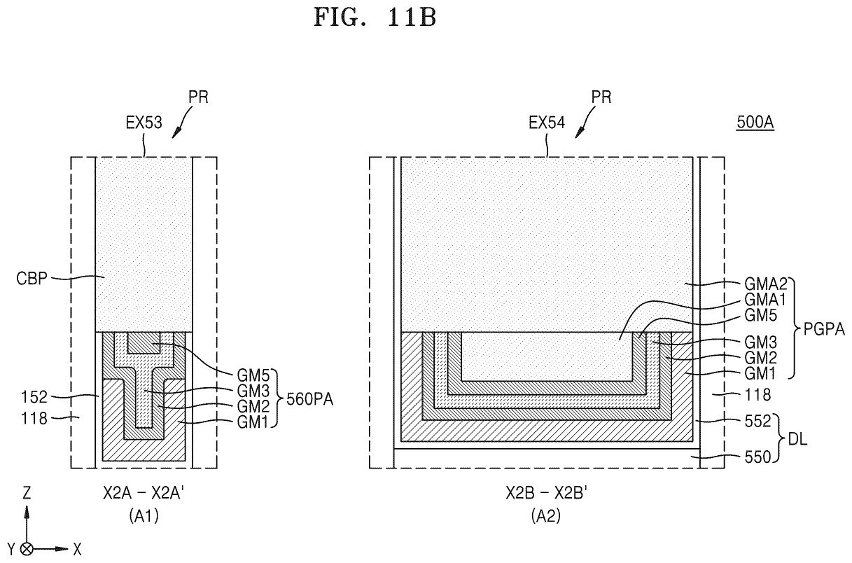

FIGS. 11A and 11B are cross-sectional views of an IC device 500A according to one or more embodiments. FIG. 11A illustrates an enlarged cross-sectional configuration of portions corresponding to portions “EX51” and “EX52” of FIG. 9A. FIG. 11B illustrates an enlarged cross-sectional configuration of portions corresponding to portions “EX53” and “EX54” of FIG. 9B. In FIGS. 11A and 11B, the same reference numerals are used to denote the same elements as in FIGS. 1 to 10B, and repeated descriptions thereof are omitted here.

Referring to FIGS. 11A and 11B, the IC device 500A may have substantially the same configuration as the IC device 500 described with reference to FIGS. 8 to 10B. However, a gate line 560NA connected to a gate contact plug CBN may be in an NMOS transistor region NR of a first device region A1, and a gate line 560PA connected to a gate contact plug CBP may be in a PMOS transistor region PR of the first device region A1. A gate line PGNA may be in an NMOS transistor region NR of a second device region A2, and a gate line PGPA may be in a PMOS transistor region PR of the second device region A2.

The gate line 560NA in the NMOS transistor region NR of the first device region A1 may have substantially the same configuration as the gate line 360D described with reference to FIG. 6D. The gate line 560PA in the PMOS transistor region PR of the first device region A1 may have substantially the same configuration as the gate line 360B described with reference to FIG. 6B.

The gate line PGNA in the NMOS transistor region NR of the second device region A2 may include a second metal-containing film GM2, a third metal-containing film GM3, a fifth metal-containing film GM5, and an inner metal film GMA1, which are sequentially stacked on a lowermost surface of the gate line PGNA, and an upper metal film GMA2 in contact with an uppermost surface of each of the second metal-containing film GM2, the third metal-containing film GM3, the fifth metal-containing film GM5, and the inner metal film GMA1. In the gate line PGNA, each of the inner metal film GMA1 and the upper metal film GMA2 may include Mo.

The gate line PGPA in the PMOS transistor region PR of the second device region A2 may include a first metal-containing film GM1, a second metal-containing film GM2, a third metal-containing film GM3, a fifth metal-containing film GM5, and an inner metal film GMA1, which are sequentially stacked on a lowermost surface of the gate line PGPA, and an upper metal film GMA2 in contact with an uppermost surface of each of the first metal-containing film GM1, the second metal-containing film GM2, the third metal-containing film GM3, the fifth metal-containing film GM5, and the inner metal film GMA1. In the gate line PGPA, each of the inner metal film GMA1 and the upper metal film GMA2 may include Mo.

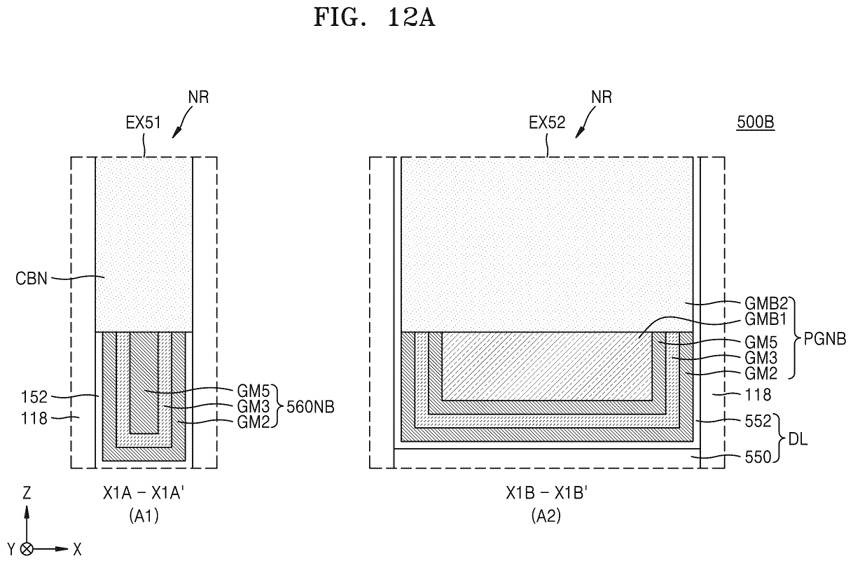

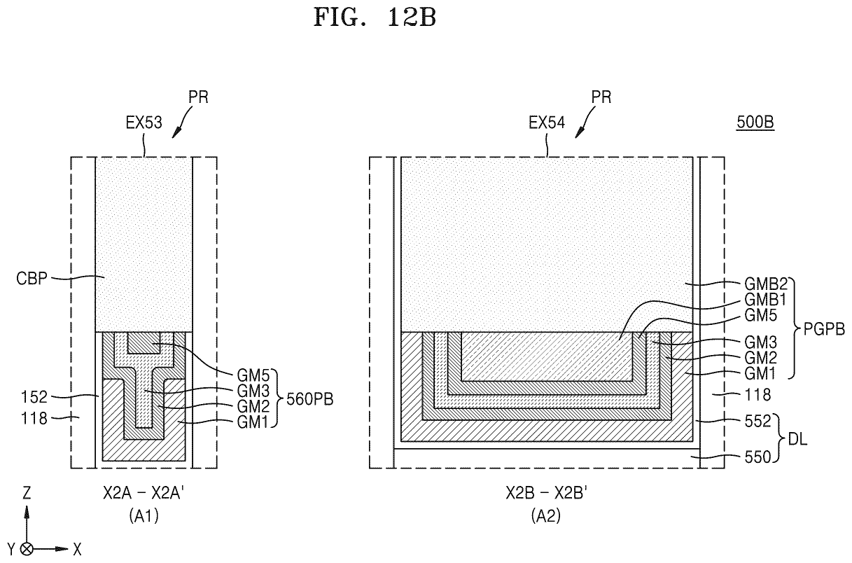

FIGS. 12A and 12B are cross-sectional views of an IC device 500B according to one or more embodiments. FIG. 12A illustrates an enlarged cross-sectional configuration of portions corresponding to portions “EX51” and “EX52” of FIG. 9A. FIG. 12B illustrates an enlarged cross-sectional configuration of portions corresponding to portions “EX53” and “EX54” of FIG. 9B. In FIGS. 12A and 12B, the same reference numerals are used to denote the same elements as in FIGS. 1 to 10B, and repeated descriptions thereof are omitted here.

Referring to FIGS. 12A and 12B, the IC device 500B may have substantially the same configuration as the IC device 500 described with reference to FIGS. 8 to 10B. However, a gate line 560NB connected to a gate contact plug CBN may be in an NMOS transistor region NR of a first device region A1, and a gate line 560PB connected to a gate contact plug CBP may be in a PMOS transistor region PR of the first device region A1. Also, a gate line PGNB may be in an NMOS transistor region NR of a second device region A2, and a gate line PGPB may be in a PMOS transistor region PR of the second device region A2.

The gate line 560NB in the NMOS transistor region NR of the first device region A1 may have the same configuration as the gate line 360D described with reference to FIG. 6D. The gate line 560PB in the PMOS transistor region PR of the first device region A1 may have the same configuration as the gate line 360B described with reference to FIG. 6B.

The gate line PGNB in the NMOS transistor region NR of the second device region A2 may include a second metal-containing film GM2, a third metal-containing film GM3, a fifth metal-containing film GM5, and an inner metal film GMB1, which are sequentially stacked on a lowermost surface of the gate line PGNB, and an upper metal film GMB2 in contact with an uppermost surface of each of the second metal-containing film GM2, the third metal-containing film GM3, the fifth metal-containing film GM5, and the inner metal film GMB1. In the gate line PGNB, the inner metal film GMB1 may include W, and the upper metal film GMB2 may include Mo.

The gate line PGPB in the PMOS transistor region PR of the second device region A2 may include a first metal-containing film GM1, a second metal-containing film GM2, a third metal-containing film GM3, a fifth metal-containing film GM5, and an inner metal film GMB1, which are sequentially stacked on a lowermost surface of the gate line PGPB, and an upper metal film GMB2 in contact with an uppermost surface of each of the first metal-containing film GM1, the second metal-containing film GM2, the third metal-containing film GM3, the fifth metal-containing film GM5, and the inner metal film GMB1. In the gate line PGPB, the inner metal film GMB1 may include W, and the upper metal film GMB2 may include Mo.

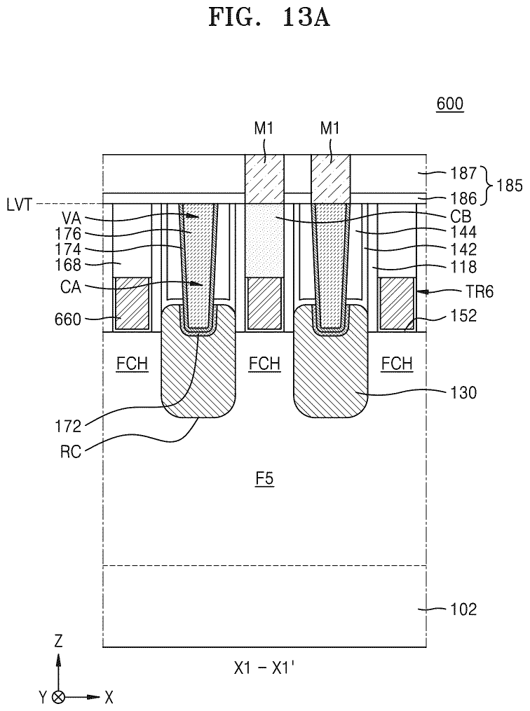

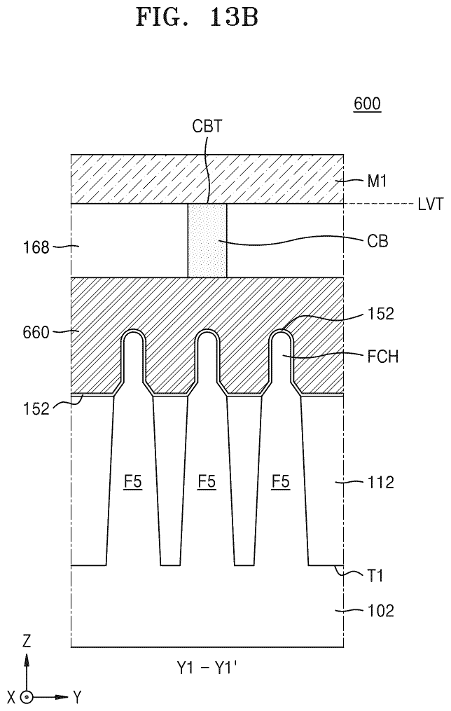

FIGS. 13A and 13B are cross-sectional views of an IC device 600 according to one or more embodiments. FIG. 13A illustrates some components in a portion corresponding to a cross-section taken along line X1-X1′ of FIG. 1, and FIG. 13B illustrates some components in a portion corresponding to a cross-section taken along line Y1-Y1′ of FIG. 1. In FIGS. 13A and 13B, the same reference numerals are used to denote the same elements as in FIGS. 1 and 2A to 2E, and repeated descriptions thereof are omitted here.

Referring to FIGS. 13A and 13B, the IC device 600 may have substantially the same configuration as the IC device 100 described with reference to FIGS. 1 and 2A to 2E. However, the IC device 600 may include a plurality of transistors TR6 including fin FETs (FinFETs). The IC device 600 may not include the plurality of nanosheet stacks NSS included in the IC device 100 described with reference to FIGS. 1 and 2A to 2E.

The IC device 600 may include a plurality of fin-type active regions F5 protruding from a substrate 102. A gate dielectric film 152 may cover a top surface and both sidewalls of the fin-type active region F5. A gate line 660 may cover the top surface and the both sidewalls of the fin-type active region F5 with the gate dielectric film 152 therebetween. An upper portion of the fin-type active region F5, which is covered by the gate dielectric film 152 and the gate line 660, may be a fin channel region FCH. Details of the gate line 660 are substantially the same as those of the gate line 160 described with reference to FIGS. 1 and 2A to 2E. Each of the plurality of transistors TR6 may be a MOS transistor having a three-dimensional (3D) structure in which a channel is formed in the top surface and both sidewalls of the fin-type active region F5.

The IC devices 100, 100A, 200, 200A, 300A, 300B, 300C, 300D, 300E, 300F, 300G, 300H, 400A, 400B, 500, 500A, 500B, and 600 described with reference to FIGS. 1 to 13 may include a gate contact plug including a metal having a lower electrical resistance than a constituent material of each of a plurality of metal-containing films included in a gate line. Accordingly, electrical properties of a contact structure connected to the gate line may be improved by inhibiting a resistance of the contact structure connected to the gate line from increasing, and electrical properties and reliability of IC devices may improve.

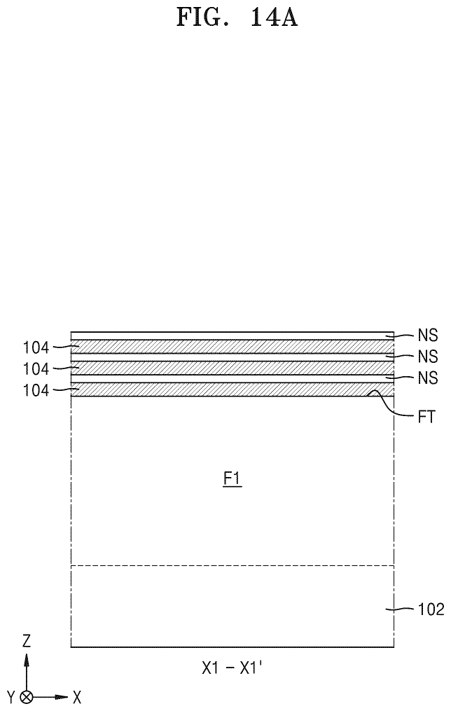

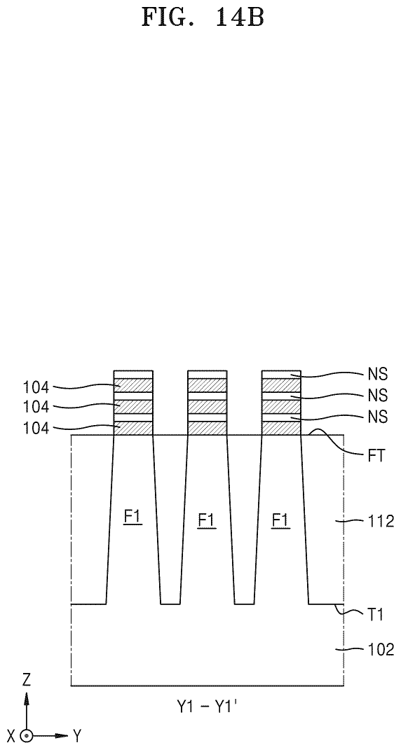

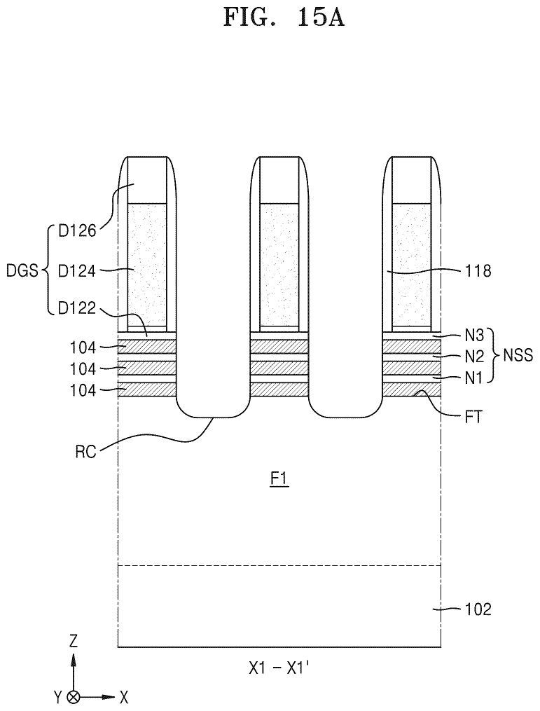

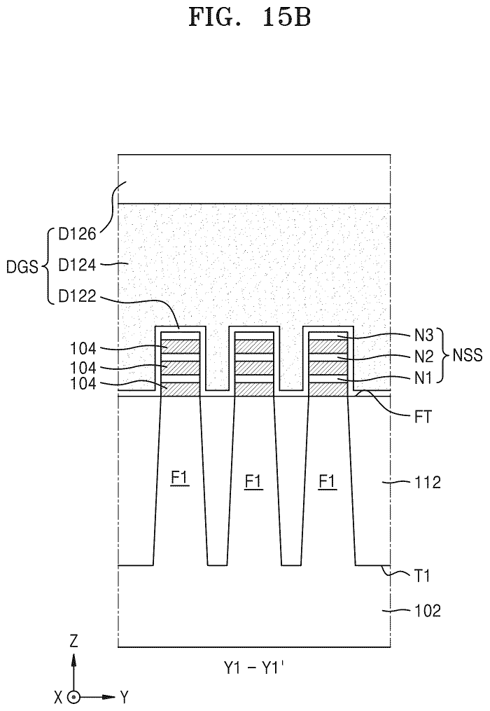

FIGS. 14A to 20 are cross-sectional views of a process sequence of a method of manufacturing an IC device, according to one or more embodiments. More specifically, FIGS. 14A, 15A, and 16 to 20 are cross-sectional views of example cross-sectional structures of a portion corresponding to a cross-section taken along line X1-X1′ of FIG. 1, according to a process sequence. FIGS. 14B and 15B are cross-sectional views of example cross-sectional structures of a portion corresponding to a cross-section taken along line Y1-Y1′ of FIG. 1, according to a process sequence. An example of a method of manufacturing the IC device 100 shown in FIGS. 1 and 2A to 2E is described with reference to FIGS. 14A to 20. In FIGS. 14A to 20, the same reference numerals are used to denote the same elements as in FIGS. 1 and 2A to 2E, and repeated descriptions thereof are omitted here.

Referring to FIGS. 14A and 14B, a plurality of sacrificial semiconductor layers 104 and a plurality of nanosheet semiconductor layers NS may be alternately stacked one-by-one on a substrate 102.

The plurality of sacrificial semiconductor layers 104 and the plurality of nanosheet semiconductor layers NS may include semiconductor materials having different etch selectivities from each other. In one or more embodiments, the plurality of nanosheet semiconductor layers NS may include a Si layer and the plurality of sacrificial semiconductor layers 104 may include a SiGe layer. In one or more embodiments, the plurality of sacrificial semiconductor layers 104 may have a constant Ge content. The SiGe layer included in the plurality of sacrificial semiconductor layers 104 may have a constant Ge content, which is selected in a range of about 5% to about 60%, for example, about 10% to about 40%. The Ge concentration of the SiGe layer included in the plurality of sacrificial semiconductor layers 104 may be variously selected as needed.

Thereafter, the plurality of sacrificial semiconductor layers 104, the plurality of nanosheet semiconductor layers NS, and the substrate 102 may be partially etched to form a plurality of fin-type active regions F1 protruding from the substrate 102. A device isolation film 112 may be formed to cover a sidewall of each of the plurality of fin-type active regions F1. A stack structure of the plurality of sacrificial semiconductor layers 104 and the plurality of nanosheet semiconductor layers NS may remain on a fin top surface FT of each of the plurality of fin-type active regions F1.

Referring to FIGS. 15A and 15B, a plurality of dummy gate structures DGS may be formed on the stack structure of the plurality of sacrificial semiconductor layers 104 and the plurality of nanosheet semiconductor layers NS.

Each of the plurality of dummy gate structures DGS may be formed to extend in a second lateral direction (Y direction). Each of the plurality of dummy gate structures DGS may have a structure in which an oxide film D122, a dummy gate layer D124, and a capping layer D126 are sequentially stacked. In one or more embodiments, the dummy gate layer D124 may include polysilicon and the capping layer D126 may include a silicon nitride film.

A plurality of insulating spacers 118 may be formed to cover both sidewalls of each of the plurality of dummy gate structures DGS. Thereafter, a portion of each of the plurality of sacrificial semiconductor layers 104 and the plurality of nanosheet semiconductor layers NS and a portion of the fin-type active region F1 may be etched by using the plurality of dummy gate structures DGS and the plurality of insulating spacers 118 as etch masks. Thus, the plurality of nanosheet semiconductor layers NS may be divided into a plurality of nanosheet stacks NSS, and a plurality of recesses RC may be formed in an upper portion of the fin-type active region F1. Each of the plurality of nanosheet stacks NSS may include a first nanosheet N1, a second nanosheet N2, and a third nanosheet N3. The plurality of recesses RC may be etched by using a dry etching process, a wet etching process, or a combination thereof.

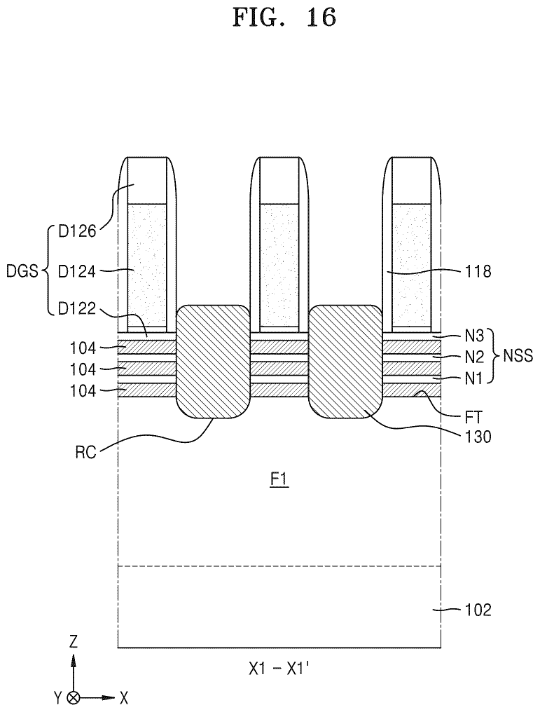

Referring to FIG. 16, in the resultant structure of FIGS. 15A and 15B, a plurality of source/drain regions 130 may be formed to fill the plurality of recesses RC.

To form the plurality of source/drain regions 130, a semiconductor material may be epitaxially grown from a surface of the fin-type active region F1 exposed at bottom surfaces of the plurality of recesses RC and a sidewall of each of the first to third nanosheets N1, N2, and N3 included in the nanosheet stack NSS.

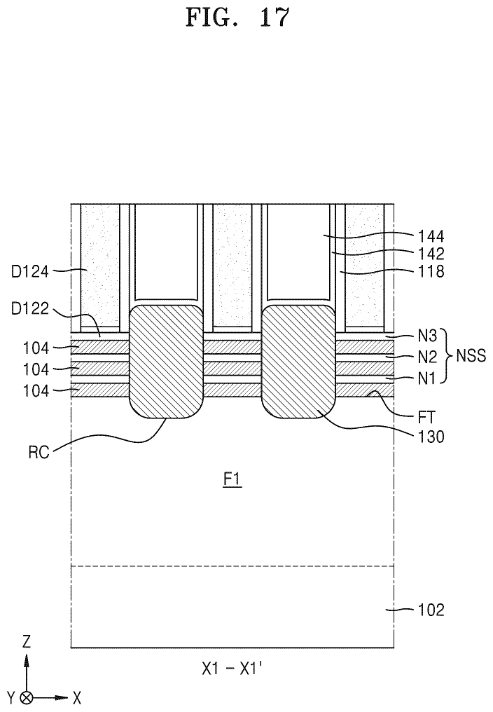

Referring to FIG. 17, an insulating liner 142 may be formed to cover the resultant structure of FIG. 16, and an inter-gate dielectric film 144 may be formed on the insulating liner 142. Thereafter, a portion of each of the insulating liner 142 and the inter-gate dielectric film 144 may be etched to expose top surfaces of a plurality of capping layers D126. Thereafter, the dummy gate layer D124 may be exposed by removing the plurality of capping layers D126, and the insulating liner 142 and the inter-gate dielectric film 144 may be partially removed such that a top surface of the inter-gate dielectric film 144 and the top surface of the dummy gate layer D124 substantially become at the same level as each other.

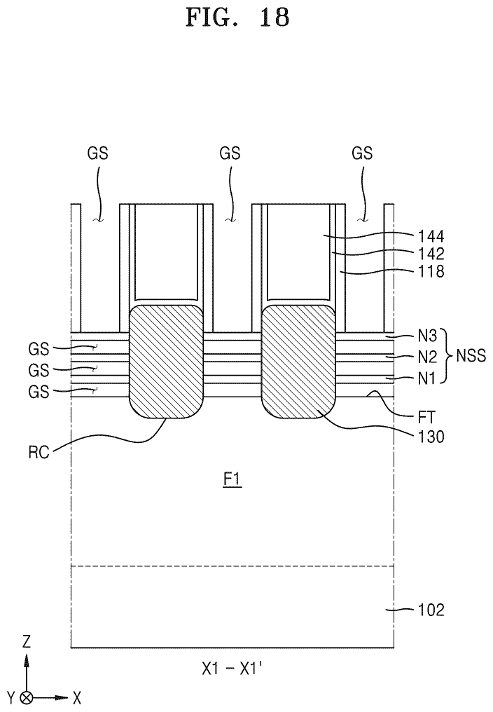

Referring to FIG. 18, a gate space GS may be prepared by removing the dummy gate layer D124 and the oxide film D122 located thereunder from the resultant structure of FIG. 17, and the plurality of nanosheet stacks NSS may be exposed through the gate space GS. Afterwards, the plurality of sacrificial semiconductor layers 104 remaining on the fin-type active region F1 may be removed through the gate space GS, and thus, the gate space GS may expand to respective spaces between the first to third nanosheets N1, N2, and N3 and a space between the first nanosheet N1 and the fin top surface FT of the fin-type active region F1. In one or more embodiments, to selectively remove the plurality of sacrificial semiconductor layers 104, differences in etch selectivity between the first to third nanosheets N1, N2, and N3 and the plurality of sacrificial semiconductor layers 104 may be used.

A liquid or gaseous etchant may be used to selectively remove the plurality of sacrificial semiconductor layers 104. In one or more embodiments, to selectively remove the plurality of sacrificial semiconductor layers 104, a CH₃COOH-based etchant, for example, an etchant including a mixture of CH₃COOH, HNO₃, and HF or an etchant including a mixture of CH₃COOH, H₂O₂, and HF may be used, without being limited thereto.

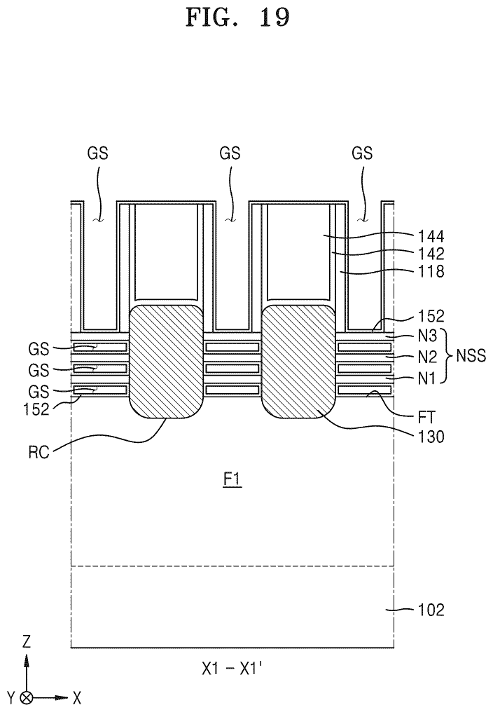

Referring to FIG. 19, in the resultant structure of FIG. 18, a gate dielectric film 152 may be formed to cover respective exposed surfaces of the first to third nanosheets N1, N2, and N3 and the fin-type active region F1. The gate dielectric film 152 may be formed by using an atomic layer deposition (ALD) process.

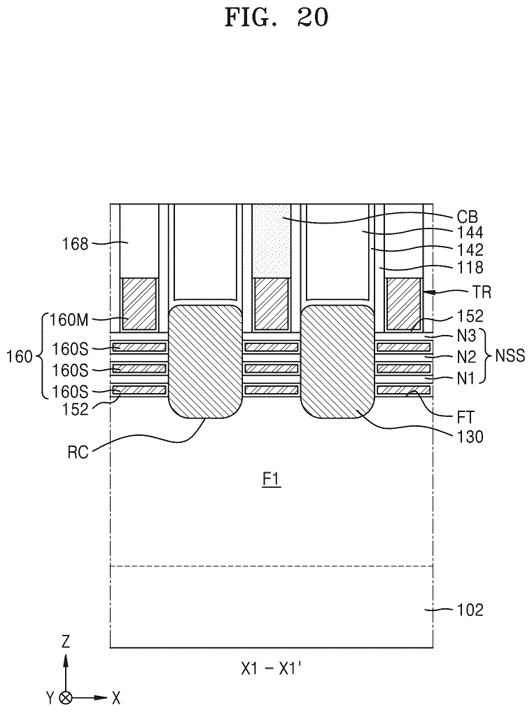

Referring to FIG. 20, a gate line 160 may be formed to fill the gate space (refer to GS in FIG. 13) on the gate dielectric film 152 and cover a top surface of the inter-gate dielectric film 144, and a conductive film may be formed to cover a top surface of the gate line 160 and fill the gate space GS. Thereafter, a portion of the conductive film may be removed to form a gate contact plug CB including the remaining portion of the conductive film. After the gate contact plug CB is formed, both sidewalls of the gate contact plug CB in the second lateral direction (Y direction) may be exposed through the gate space GS, and the top surface of the gate line 160 may be exposed around the gate contact plug CB.

Next, a capping insulating pattern 168 filling the remaining spaces of the gate space GS may be formed to cover the top surface of the gate line 160, which is exposed around the gate contact plug CB, and contact the both sidewalls of the gate contact plug CB in the second lateral direction (Y direction).

Thereafter, in the resultant structure of FIG. 20, a plurality of source/drain contact holes exposing the source/drain regions 130 may be formed to pass through an insulating structure including the insulating liner 142 and the inter-gate dielectric film 144. A partial region of the source/drain region 130 may be removed by using anisotropic etching process through each of the plurality of source/drain contact holes, and a metal silicide film 172 may be formed on the source/drain region 130 exposed at a bottom side of each of the plurality of source/drain contact holes.

Afterwards, the inside of each of the plurality of source/drain contact holes may be filled by a conductive barrier film 174 and a contact plug 176, and a portion of each of the conductive barrier film 174 and the contact plug 176 may be removed. Thus, a source/drain contact CA and a via contact VA, which are integrally connected to each other, may be formed as shown in FIGS. 2A and 2D.

Thereafter, as shown in FIGS. 2A and 2B, an etch stop film 186 and an interlayer insulating film 187 may be sequentially formed to cover a top surface of the via contact VA, a conductive top surface CBT of the gate contact plug CB, and a top surface of the capping insulating pattern 168 to form an upper insulating structure 185. An upper wiring layer M1 may be formed to pass through the upper insulating structure 185, and thus, the IC device 100 may be manufactured.

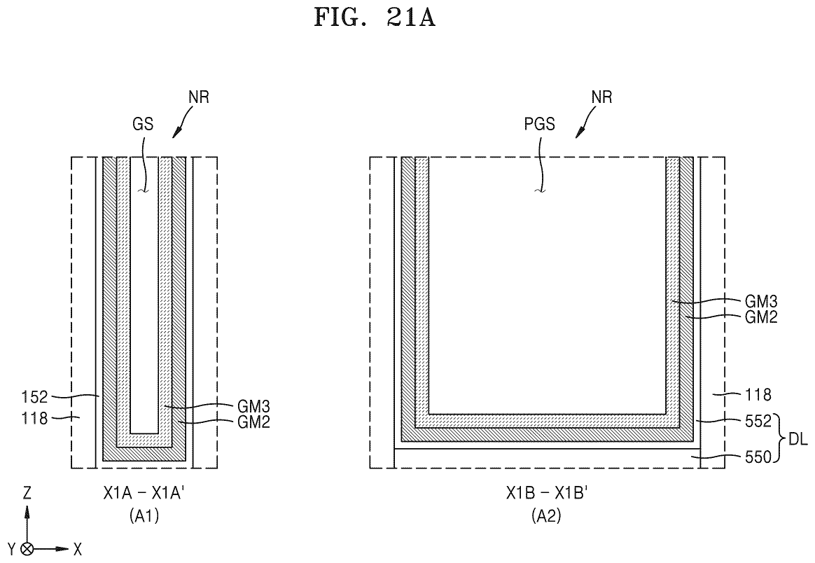

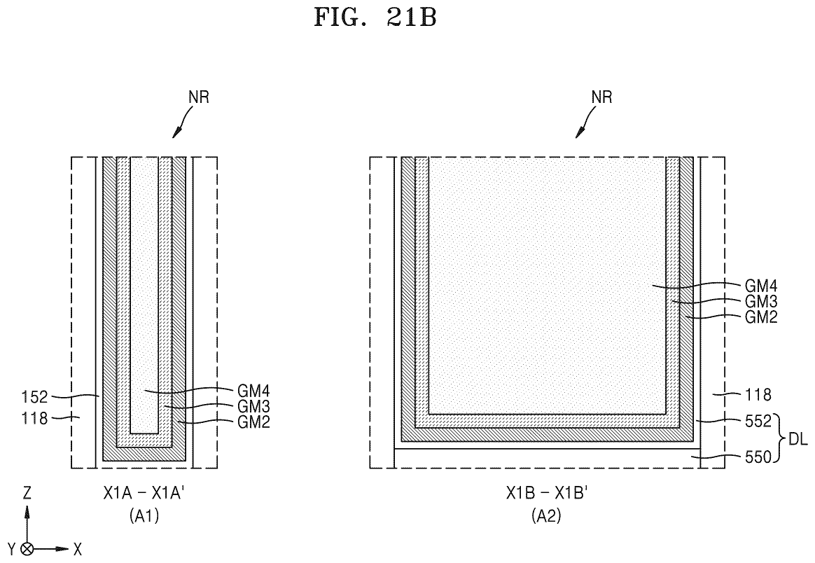

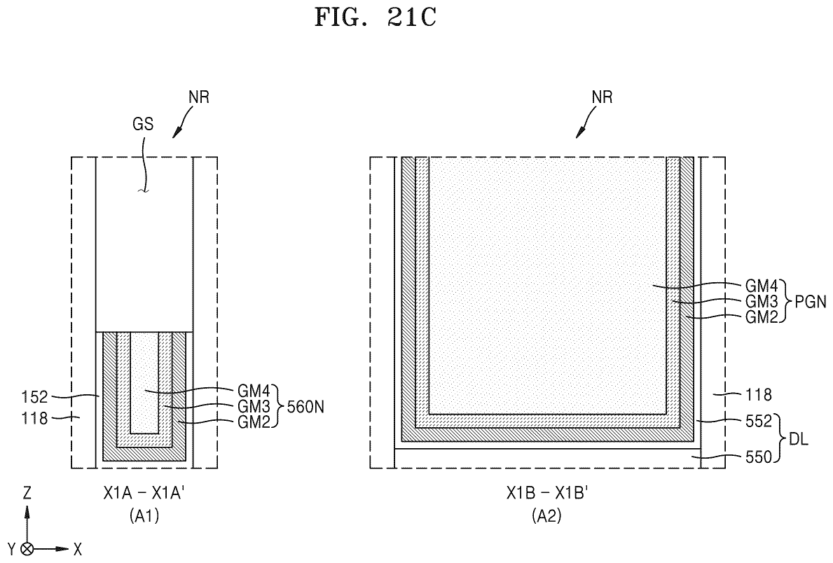

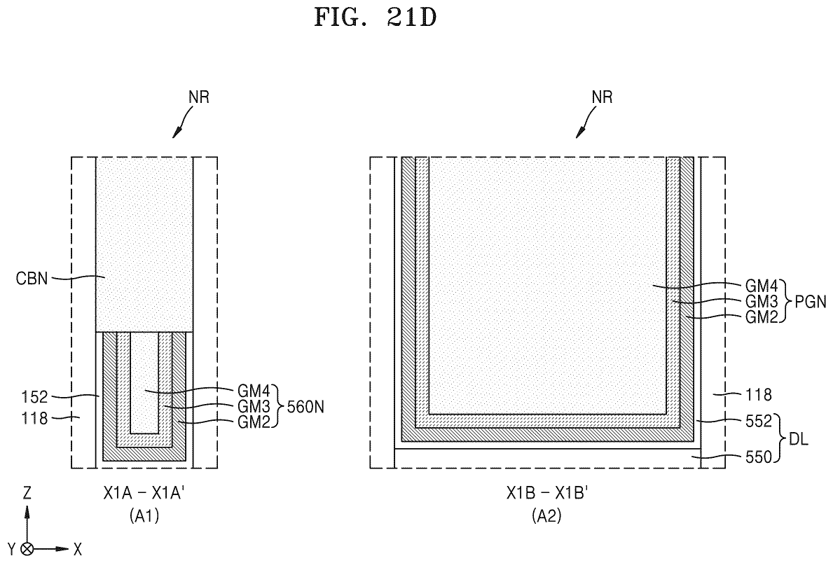

FIGS. 21A to 21D are cross-sectional views of a process sequence of a method of manufacturing the IC device 500 shown in FIGS. 8, 9A, 9B, 10A, and 10B, according to one or more embodiments. FIGS. 21A to 21D illustrate enlarged cross-sectional configurations of portions corresponding to portions “EX51” and “EX52” of FIG. 9A, according to a process sequence.

Referring to FIG. 21A, the processes described with reference to FIGS. 14A to 19 may be performed in an NMOS transistor region NR of a first device region A1 on a substrate 102. While the processes described with reference to FIGS. 14A to 19 are being performed in the NMOS transistor region NR of the first device region A1, a gate space PGS defined by a pair of insulating spacers 118 may be exposed on an active region ACN in an NMOS transistor region NR of a second device region A2, and a lower gate dielectric film 550 and an upper gate dielectric film 552 may be sequentially formed through the gate space PGS to form a gate dielectric film DL.

Afterwards, a second metal-containing film GM2 and a third metal-containing film GM3 may be sequentially formed to conformally cover exposed surfaces in a gate space GS of the first device region A1 and the gate space PGS of the second device region A2.

Referring to FIG. 21B, in the first device region A1 and the second device region A2, the gate spaces GS and PGS may be filled by a fourth metal-containing film GM4 on the third metal-containing film GM3.

Referring to FIG. 21C, in the resultant structure of FIG. 21B, a portion of each of the second metal-containing film GM2, the third metal-containing film GM3, and the fourth metal-containing film GM4 may be selectively removed only in the first device region A1, among the first device region A1 and the second device region A2. Thus, a height of each of the second metal-containing film GM2, the third metal-containing film GM3, and the fourth metal-containing film GM4 may be reduced, and an upper portion of the gate space GS may be emptied again.

Referring to FIG. 21D, in the resultant structure of FIG. 21C, a metal film filling the gate space GS may be formed on each of the second metal-containing film GM2, the third metal-containing film GM3, and the fourth metal-containing film GM4. Thereafter, a portion of the metal film may be removed to expose a top surface of each of the second metal-containing film GM2, the third metal-containing film GM3, and the fourth metal-containing film GM4, and a gate contact plug CBN including the remaining portion of the metal film may be formed.

Thereafter, a capping insulating pattern may be formed to cover the top surface of each of the second metal-containing film GM2, the third metal-containing film GM3, and the fourth metal-containing film GM4 that are exposed around the gate contact plug CBN. The capping insulating pattern may be formed to fill the gate space GS on each of the second metal-containing film GM2, the third metal-containing film GM3, and the fourth metal-containing film GM4. The capping insulating pattern may have substantially the same configuration as the capping insulating pattern 168 described with reference to FIGS. 2A to 2C.

In other embodiments, by making various changes and modifications in the scope of the disclosure, the gate contact plug CBN may be formed to have a structure integrally connected to a portion of the gate line 560N. To this end, for example, as described with reference to FIG. 21D, a portion of each of the second metal-containing film GM2, the third metal-containing film GM3, and the fourth metal-containing film GM4 may be selectively removed only in the first device region A1 to reduce a height of each of the second metal-containing film GM2, the third metal-containing film GM3, and the fourth metal-containing film GM4. Thereafter, a process of removing the fourth metal-containing film GM4 may be added. Thereafter, when a metal film for forming the gate contact plug CBN is formed, the metal film may be formed to also fill a space from which the fourth metal-containing film GM4 is removed. Afterwards, a portion of the metal film may be removed to form the gate contact plug CBN. A portion of the metal film, which fills the space from which the fourth metal-containing film GM4 is removed, may constitute a portion of the gate line 560N.

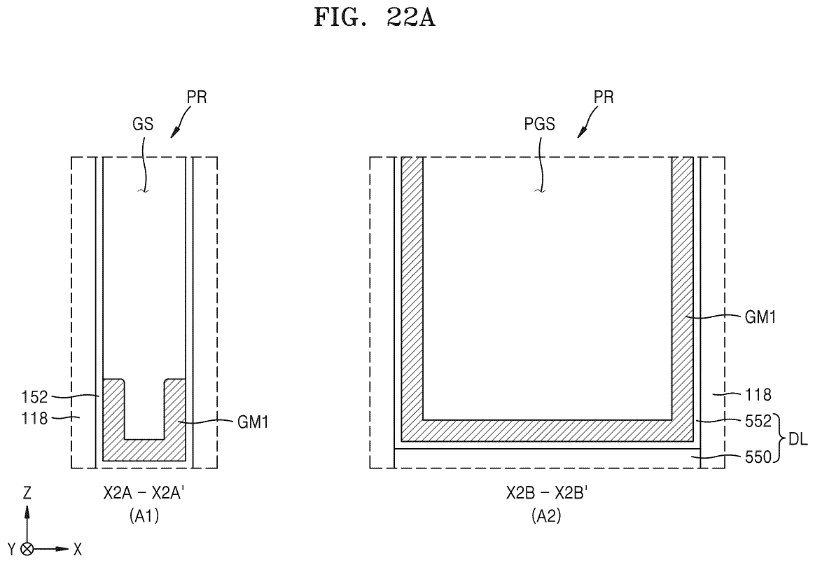

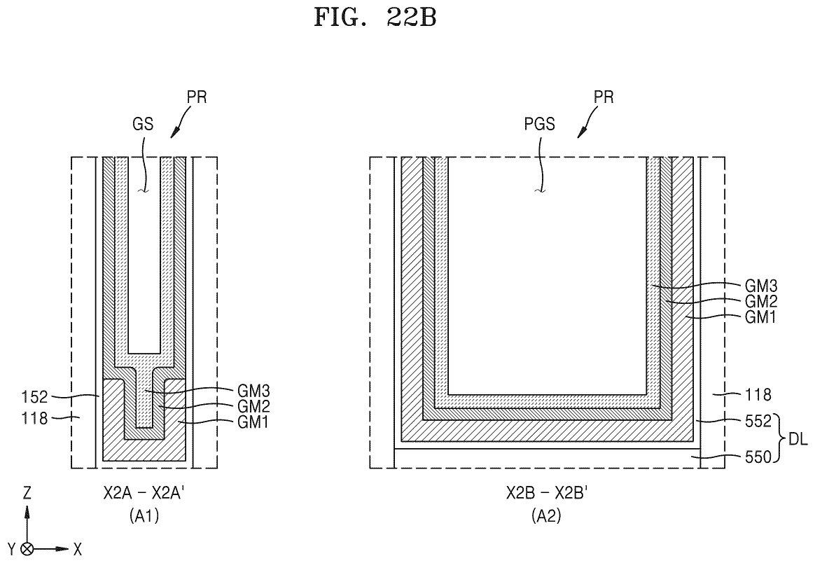

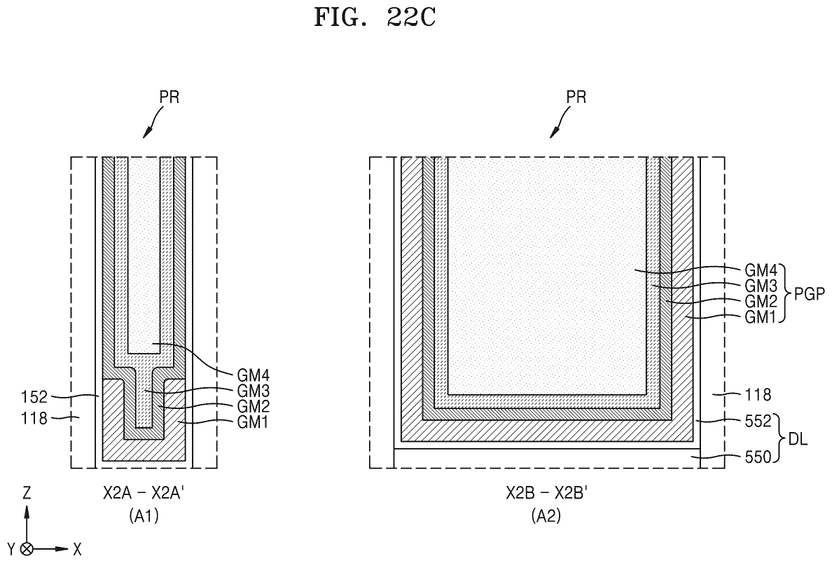

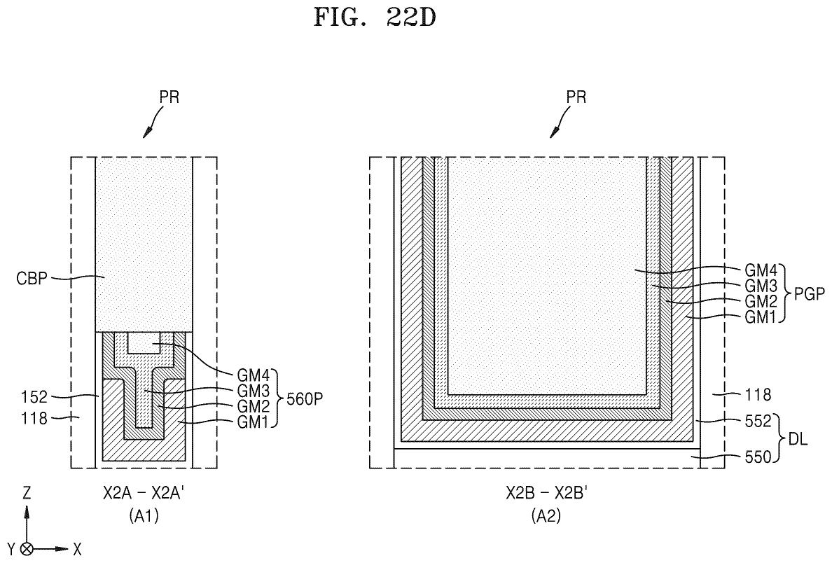

FIGS. 22A to 22D are cross-sectional views of a process sequence of a method of manufacturing the IC device 500 shown in FIGS. 8, 9A, 9B, 10A, and 10B, according to one or more embodiments. FIGS. 22A to 22D illustrate enlarged cross-sectional configurations of portions corresponding to portions “EX53” and “EX54” of FIG. 9B, according to a process sequence.

Referring to FIG. 22A, the processes described with reference to FIGS. 14A to 19 may be performed in a PMOS transistor region PR of a first device region A1 on a substrate 102. While the processes described with reference to FIGS. 14A to 19 are being performed in the PMOS transistor region PR of the first device region A1, a gate space PGS defined by a pair of insulating spacers 118 may be exposed on an active region ACP in a PMOS transistor region PR of a second device region A2, and a lower gate dielectric film 550 and an upper gate dielectric film 552 may be sequentially formed through the gate space PGS to form a gate dielectric film DL.

Thereafter, a first metal-containing film GM1 may be formed to conformally cover exposed surfaces in the gate space GS of the first device region A1 and the gate space PGS of the second device region A2, and a portion of the first metal-containing film GM1 may be selectively removed only in the first device region A1, among the first device region Al and the second device region A2, to reduce a height of the first metal-containing film GM1.

Referring to FIG. 22B, in the gate space GS of the first device region A1 and the gate space PGS of the second device region A2, a second metal-containing film GM2 and a third metal-containing film GM3 may be sequentially formed on the first metal-containing film GM1.

Referring to FIG. 22C, in the first device region A1 and the second device region A2, the gate spaces GS and PGS on the third metal-containing film GM3 may be filled by a fourth metal-containing film GM4.

Referring to FIG. 22D, in the resultant structure of FIG. 22C, a portion of each of the second metal-containing film GM2, the third metal-containing film GM3, and the fourth metal-containing film GM4 may be selectively removed only in the first device region A1, among the first device region A1 and the second device region A2. Thus, a height of each of the second metal-containing film GM2, the third metal-containing film GM3, and the fourth metal-containing film GM4 may be reduced, and an upper portion of the gate space GS may be emptied again.

Thereafter, the processes similar to the processes described with reference to FIG. 21D may be performed. A gate contact plug CBN may be formed to cover an uppermost surface of each of the second metal-containing film GM2, the third metal-containing film GM3, and the fourth metal-containing film GM4. Also, a capping insulating pattern may be formed to fill the gate space GS around the gate contact plug CBP. The capping insulating pattern may have substantially the same configuration as the capping insulating pattern 168 described with reference to FIGS. 2A to 2C.

In other embodiments, by making various changes and modifications in the scope of the disclosure, the gate contact plug CBP may be formed to have a structure integrally connected to a portion of the gate line 560P. To this end, for example, as described with reference to FIG. 22D, a portion of each of the second metal-containing film GM2, the third metal-containing film GM3, and the fourth metal-containing film GM4 may be selectively removed only in the first device region A1 to reduce a height of each of the second metal-containing film GM2, the third metal-containing film GM3, and the fourth metal-containing film GM4. Thereafter, a process of removing the fourth metal-containing film GM4 may be added. Thereafter, when a metal film for forming the gate contact plug CBP is formed, the metal film may be formed to also fill a space from which the fourth metal-containing film GM4 is removed. Afterwards, a portion of the metal film may be removed to form the gate contact plug CBP. A portion of the metal film, which fills the space from which the fourth metal-containing film GM4 is removed, may constitute a portion of the gate line 560P.

Although the methods of manufacturing the IC device 100 shown in FIGS. 1 and 2A to 2E and the IC device 500 shown in FIGS. 8, 9A, 9B, 10A, and 10B have been described with reference to FIGS. 14A to 22D, it will be understood that IC devices according to one or more embodiments and IC devices having various other structures may be manufactured by making various modifications and changes within the scope of the disclosure.

While the disclosure has been particularly shown and described with reference to one or more embodiments thereof, it will be understood that various changes in form and details may be made therein without departing from the spirit and scope of the following claims.

What is claimed is:

1. An integrated circuit device comprising:
a fin-type active region extending in a first lateral direction on a substrate;
a pair of insulating spacers extending in a second lateral direction on the fin-type active region and the substrate, wherein the pair of insulating spacers defining a first space, and the second lateral direction intersects with the first lateral direction;
a gate line covering the fin-type active region in the first space and extending in the second lateral direction;
a gate dielectric film in contact with a bottom surface of the gate line and sidewalls of the gate line in the first space, the gate dielectric film extending in the second lateral direction;
a gate contact plug having a conductive bottom surface in contact with a top contact portion of a top surface of the gate line in the first space; and
a capping insulating pattern comprising an insulating bottom surface, a pair of first insulating sidewalls, and a second insulating sidewall,
wherein the insulating bottom surface is in contact with a local top surface adjacent to the top contact portion of the top surface of the gate line in the first space, the pair of first insulating sidewalls are in contact with the pair of insulating spacers, and the second insulating sidewall is in contact with the gate contact plug, and
wherein an insulating top surface of the capping insulating pattern and a conductive top surface of the gate contact plug extend along one plane.

2. The integrated circuit device of claim 1, wherein a constituent material of the gate contact plug has a lower electrical resistance than a constituent material of at least a portion of the gate line.

3. The integrated circuit device of claim 1, wherein a top surface of each of the pair of insulating spacers extends along the one plane.

4. The integrated circuit device of claim 1,
wherein the conductive bottom surface of the gate contact plug comprises a first end portion, and the conductive top surface of the gate contact plug comprises a second end portion, and
wherein the first end portion and the second end portion are in contact with the pair of insulating spacers.

5. The integrated circuit device of claim 1,
wherein the gate contact plug comprises a single metal film, and
wherein a metal nitride film is not between the single metal film and the pair of insulating spacers.

6. The integrated circuit device of claim 1, wherein the gate contact plug is integrally connected to at least a portion of the gate line.

7. The integrated circuit device of claim 1, further comprising:
a source/drain region on the fin-type active region;
an insulating structure covering the source/drain region;
a source/drain contact passing through the insulating structure in a vertical direction, wherein the source/drain contact is connected to the source/drain region; and
a via contact connected to the source/drain contact,
wherein a top surface of the via contact extends along the one plane.

8. The integrated circuit device of claim 1,
wherein the gate line comprises a metal-containing film portion and a metal film portion, wherein the metal-containing film portion comprises titanium nitride (TiN), tantalum nitride (TaN), titanium aluminum nitride (TiAlN), titanium aluminum carbide (TiAlC), or a combination thereof, and the metal film portion comprises molybdenum (Mo), ruthenium (Ru), copper (Cu), tungsten (W), or a combination thereof, and
wherein the gate contact plug comprises a metal selected from Mo, Ru, Cu, and W.

9. An integrated circuit device comprising:
a substrate comprising a first device region and a second device region;
a fin-type active region on the substrate in the first device region, the fin-type active region extending in a first lateral direction;
a first gate line extending in a second lateral direction on the fin-type active region and the substrate, the first gate line comprising a first width in the first lateral direction, wherein the first gate line is in the first device region, and the second lateral direction intersects with the first lateral direction;
a first gate dielectric film covering a bottom surface of the first gate line and sidewalls of the first gate line, the first gate dielectric film extending in the second lateral direction;
a gate contact plug comprising a conductive bottom surface in contact with a top contact portion of a top surface of the first gate line;
a capping insulating pattern comprising an insulating bottom surface and an insulating sidewall, wherein the insulating bottom surface is in contact with a local top surface adjacent to the top contact portion of the top surface of the first gate line, and the insulating sidewall is in contact with the gate contact plug;
a second gate line on an active region in the second device region, the second gate line comprising a second width in the first lateral direction, wherein the second gate line is in the second device region, and the second width is greater than the first width; and
a second gate dielectric film between the second gate line and the active region,
wherein, in the first device region, an insulating top surface of the capping insulating pattern and a conductive top surface of the gate contact plug extend along one plane, and
wherein the conductive top surface of the gate contact plug in the first device region comprises a same material as a top surface of the second gate line in the second device region.

10. The integrated circuit device of claim 9, wherein the first gate line and the second gate line have different stack structures.

11. The integrated circuit device of claim 9,
wherein each of the first gate line and the second gate line further comprises at least one metal-containing film comprising at least one material selected from a nitride of a first metal and a carbide of the first metal,
wherein the gate contact plug further comprises a second metal, the second metal being a different metal from the first metal, and
wherein the second gate line further comprises a metal film comprising a bottom surface and sidewalls covered by the at least one metal-containing film, wherein the metal film comprises the second metal.

12. The integrated circuit device of claim 9,
wherein each of the first gate line and the second gate line further comprises a plurality of metal-containing films, wherein each metal-containing film of each plurality of metal-containing films comprises different materials from each of the other metal-containing films of the plurality of metal-containing films, and
wherein a first vertical distance from an uppermost surface of each of the plurality of metal-containing films included in the first gate line to a lowermost surface of the first gate line is less than a second vertical distance from an uppermost surface of each of the plurality of metal-containing films included in the second gate line to a lowermost surface of the second gate line.

13. The integrated circuit device of claim 9,
wherein each of the first gate line and the second gate line comprises a plurality of metal-containing films, wherein each metal-containing film of each plurality of metal-containing films comprises different materials from each of the other metal-containing film of the plurality of metal-containing films,
wherein the gate contact plug is in contact with an uppermost surface of each of the plurality of metal-containing films included in the first gate line, and
wherein the second gate line further comprises an upper metal film in contact with the uppermost surface of each of the plurality of metal-containing films included in the second gate line.

14. The integrated circuit device of claim 9,
wherein each of the first gate line and the second gate line comprises a plurality of metal-containing films, wherein each metal-containing film of each plurality of metal-containing films comprises different materials from each of the other metal-containing film of the plurality of metal-containing films,
wherein the gate contact plug further comprises a first metal having a lower electrical resistance than a constituent material of each of the plurality of metal-containing films included in the first gate line, and
the second gate line comprises an upper metal film in contact with an uppermost surface of each of the plurality of metal-containing films included in the second gate line, the upper metal film comprising the first metal.

15. The integrated circuit device of claim 9, further comprising:
a pair of first insulating spacers covering both sidewalls of each of the first gate line and the gate contact plug in the first lateral direction; and
a pair of second insulating spacers covering both sidewalls of the second gate line in the first lateral direction,
wherein the gate contact plug further comprises a first metal film comprising a single metal, and sidewalls of the gate contact plug are in contact with the pair of first insulating spacers, and
wherein the second gate line further comprises a second metal film comprising a same material as the first metal film, and the second metal film is separate from the pair of second insulating spacers.

16. The integrated circuit device of claim 9, wherein the gate contact plug further comprises a same material as at least a portion of the first gate line.

17. The integrated circuit device of claim 9, further comprising:
a source/drain region on the fin-type active region;
an insulating structure covering the source/drain region;
a source/drain contact passing through the insulating structure in a vertical direction, wherein the source/drain contact is connected to the source/drain region; and
a via contact connected to the source/drain contact,
wherein a top surface of the via contact extends along the one plane.

18. An integrated circuit device comprising:
a substrate comprising an N-type metal-oxide-semiconductor (NMOS) transistor region and a P-type metal-oxide-semiconductor (PMOS) transistor region;
a fin-type active region extending in a first lateral direction in the NMOS transistor region or the PMOS transistor region;
a nanosheet stack separate from a fin top surface of the fin-type active region in a vertical direction, wherein the nanosheet stack faces the fin top surface of the fin-type active region, and the nanosheet stack comprises at least one nanosheet;
a pair of insulating spacers extending in a second lateral direction in a selected one of the NMOS transistor region and the PMOS transistor region corresponding to a location of the fin-type active region, the pair of insulating spacers defining a first space, wherein the second lateral direction intersects with the first lateral direction;
a gate line surrounding the at least one nanosheet and extending in the second lateral direction in the first space;
a gate dielectric film extending in the second lateral direction in the first space, the gate dielectric film comprising a portion in contact with a bottom surface and side surfaces of the gate line and each of the at least one nanosheet;
a gate contact plug comprising a conductive bottom surface in contact with a top contact portion of the gate line in the first space;
a capping insulating pattern comprising an insulating bottom surface, a pair of first insulating sidewalls, and a second insulating sidewall,
wherein the insulating bottom surface is in contact with a local top surface adjacent to the top contact portion of the gate line in the first space, the pair of first insulating sidewalls are in contact with the pair of insulating spacers, and the second insulating sidewall is in contact with the gate contact plug, and
wherein an insulating top surface of the capping insulating pattern and a conductive top surface of the gate contact plug extend along one plane.

19. The integrated circuit device of claim 18,
wherein the gate line is in the NMOS transistor region,
wherein the gate line comprises a metal nitride film and a metal carbide film which are sequentially stacked on the gate dielectric film,
wherein the conductive bottom surface of the gate contact plug is in contact with an uppermost surface of each of the metal nitride film and the metal carbide film, and
wherein the gate contact plug further comprises a metal film comprising a lower electrical resistance than a constituent material of each of the metal nitride film and the metal carbide film.

20. The integrated circuit device of claim 18,
wherein the gate line is in the PMOS transistor region,
wherein the gate line comprises a first metal nitride film, a second metal nitride film, and a metal carbide film, which are sequentially stacked on the gate dielectric film,
wherein the conductive bottom surface of the gate contact plug is in contact with an uppermost surface of each of the first metal nitride film, the second metal nitride film, and the metal carbide film, and
wherein the gate contact plug further comprises a metal film comprising a lower electric resistance than a constituent material of each of the first metal nitride film, the second metal nitride film, and the metal carbide film.
